(19) United States
(12) Patent Application Publication
(10) Pub. No.: US 2017/0373647 A1
(43) Pub. Date: Dec. 28, 2017

(54) Linearity Enhancement Method For Low-Power Low-Noise Amplifiers Biased In The Subthreshold Region

(71) Applicant: Northeastern University, Boston, MA (US)

(72) Inventors: Chun-hsiang Chang, Cupertino, CA (US); Marvin Onabajo, Jamaica Plain, MA (US)

(21) Appl. No.: 15/535,338

(22) PCT Filed: Feb. 16, 2016
(86) PCT No.: PCT/US2016/018056

§ 371 Date: Jun. 12, 2017

Related U.S. Application Data
(60) Provisional application No. 62/118,148, filed on Feb. 19, 2015.

(51) Int. Cl. H03F 1/32; H03F 1/22; H03F 3/193

(52) U.S. Cl. CPC H03F 1/3205; H03F 3/193; H03F 1/223; H03F 2200/451; H03F 2200/294

(57) ABSTRACT

An amplifier and corresponding method include a field-effect transistor (FET) amplifier and a cascode FET. Each FET may operate with a positive ratio between its third-order nonlinearity coefficient and its linear gain. An inductor added at a gate of the cascode FET, operatively coupled with other components in a circuit, results in a first equivalent impedance looking into an input of the cascode FET. The first equivalent impedance may substantially offset a distortion output of the FET amplifier based upon the added inductor. The inductor operatively coupled with the circuit may result in a second equivalent impedance looking out of the gate of the cascode FET. The second equivalent impedance may substantially offset a distortion output of the cascode FET based upon the added inductor. In addition, a programmable capacitor connected between the gate and drain of the cascode FET may further substantially offset a distortion output of each FET.

### RELATED APPLICATION

This application claims the benefit of U.S. Provisional Application No. 62/118,148, filed on Feb. 19, 2015. The entire teachings of the above application are incorporated herein by reference.

### GOVERNMENT SUPPORT

This invention was made with government support under Grant No. 1349692 from The National Science Foundation and Grant No. 1451213 from The National Science Foundation. The Government has certain rights in the invention.

### BACKGROUND

Prevalent third-order intermodulation intercept point (IIP3) improvement methods for low-power low-noise amplifiers (LNAs) in narrowband applications may include two approaches. The first approach may use an auxiliary transistor biased in the weak inversion region to cancel the third-order nonlinearity coefficient (g₃), but in such an approach, the main transistor may be operated in a strong inversion region with higher linear transconductance (g₁=gₘ) than in the auxiliary path (see for example, the following publications which are hereby incorporated by reference in their entirety herein: Aparin, V., “Linearization of CDMA Receiver Front-Ends,” Ph. D. dissertation, Univ. California, San Diego, Calif., USA, 2005, hereinafter “Linearization of CDMA Receiver Front-Ends;” and Aparin, V. and Larson, L. E., “Modified Derivative Superposition Method for Linearizing FET Low-Noise Amplifier,” IEEE Trans. on Microwave Theory and Techniques, vol. 53, no. 2, pp. 571-581, February 2005, hereinafter “Modified Derivative Superposition Method for Linearizing FET Low-Noise Amplifier”). The second approach may operate the main transistor between the moderate inversion and subthreshold regions for finding the optimum bias zone (see for example the following publication, which is hereby incorporated by reference in its entirety herein, Fiorelli, R., Silveria, F. and Peralias, E., “MOST Moderate-Weak-Inversion Region as the Optimum Design Zone for CMOS 2.4-GHz CS-LNAs,” IEEE Trans. on Microwave Theory and Techniques, vol. 62, no. 3, pp. 556-566, March 2014, hereinafter “MOST Moderate-Weak-Inversion Region as the Optimum Design Zone for CMOS 2.4-GHz CS-LNAs”).

### SUMMARY OF THE INVENTION

Thus, a method for reporting measurements of radio frequency (RF) amplifiers using transistors biased in the subthreshold region (and/or weak inversion region) is needed. As such, the proposed approach is directed to an amplifier and corresponding method to improve the third-order distortion performance of a subthreshold (and/or weak inversion) common-source cascode low-noise amplifier (LNA) without addition of an auxiliary transistor.

The proposed approach may include a linearization method (and/or amplifier and/or proposed LNA) to improve the third-order distortion performance of a subthreshold common-source cascode low-noise amplifier (LNA) by using passive components without extra power consumption. An inductor may be added between the gate of the cascode transistor and the power supply, which may improve the third-order intermodulation intercept point (IIP3) of the LNA. An inductor may be added between the gate of the cascode transistor and the power supply. A digitally programmable capacitor may be connected between the gate and drain of the cascode transistor. The inductor and/or the digitally programmable capacitor thereby may improve the third-order intermodulation intercept point (IIP3) of the proposed LNA.

The mechanism that underlies the linearity improvement may be analyzed under consideration of the LNA's input stage and its cascode stage. An 1.8 GHz LNA may be designed and fabricated using 0.11 μm complementary metal-oxide semiconductor (CMOS) technology. Measurement results reveal that the linearized low-power LNA may have a 14.8 dB voltage gain, a 3.7 dB noise figure, and/or a -3.7 dBm IIP3 with a power consumption of 0.336 mW.

The proposed LNA may include an amplifier (and corresponding method) that may include a field-effect transistor (FET) amplifier (M₁, or transistor M₁ herein) and a cascode FET (M₂, or transistor M₂ herein). Descriptions herein with are understood to apply to the proposed LNA (amplifier and/or the corresponding method). The proposed approach may also include a buffer (M_{buffer} and/or associated buffer circuitry), which may be referred to note that “the buffer,” “the output buffer,” and/or “buffer stage” herein. The “combined” LNA or “proposed combined” LNA may refer herein to any combination of M₁, M₂, and/or M_{bufffer}. The proposed approach (amplifier and method) may include, but is not limited to a linear amplifier, a low-noise amplifier, and/or any other type of amplifier. The proposed amplifier may be referred to as “the amplifier,” “the proposed amplifier,” “the proposed LNA,” “the LNA,” “the proposed linearized LNA,” “the subthreshold LNA,” “the proposed linearized subthreshold LNA,” “the subthreshold RF circuit,” and/or “the proposed subthreshold RF circuit” herein.

The amplifier (and corresponding method) may include a cascode FET (M₂) in series with the FET amplifier (M₁). Each FET may operate with a respective third-order nonlinearity coefficient (g₃) and a respective linear gain (g₁). Each respective ratio (g₃/g₁) of the respective third-order nonlinearity coefficient (g₃) to the respective linear gain (g₁) may be positive. The amplifier (and corresponding method) may include an inductor (L_{g2}) added at a gate of the cascode FET (M₂). The inductor (L_{g2}) may be operatively coupled with other components in a circuit resulting in a first equivalent impedance looking into an input (e.g., source terminal) of the cascode FET (M₂) from the FET amplifier (M₁). The first equivalent impedance may substantially offset a distortion output of the FET amplifier (M₁) based upon the added inductor (L_{g2}).

The inductor (L_{g2}) may be operatively coupled with the other components in the circuit resulting in a second equivalent impedance looking out of the gate of the cascode FET (M₂). The second equivalent impedance may substantially offset a distortion output of the cascode FET (M₂) based upon the added inductor (L_{g2}).

The FET amplifier (M₁) and/or the cascode FET (M₂) may operate in a range of one or more operating frequencies. The range of each of the one or more operating frequencies may be programmable. Based upon programming the range, the FET amplifier (M₁) and/or the cascode FET (M₂) may amplify signals within a bandwidth (e.g., narrow bandwidth) at (and/or around) one or more of the operating frequencies. The proposed approach (amplifier and corresponding method) may substantially offset a distortion output within the bandwidth of the FET amplifier (M₁) and/or the cascode FET (M₂).

The FET amplifier and/or the cascode FET may operate in a range (optionally a programmable range) of one or more operating frequencies between 0.3 GHz and 6 GHz (and/or a higher frequency and/or lower frequency in other CMOS technologies and/or other technologies). The amplifier (and method) may amplify an output of the FET amplifier and/or an output of the cascode FET within a selected bandwidth associated with the one or more operating frequencies. The distortion output of the FET amplifier and/or the distortion output of the cascode FET may be substantially offset within the selected bandwidth.

The FET amplifier (M₁) and/or the cascode FET (M₂) may operate in a weak inversion region and/or subthreshold region. The other components may include a capacitor (C_{gd2}_{_}ₑₓₜ) connected between the gate of the cascode FET (M₂) and a drain of the cascode FET (M2). The capacitor (C_{gd2}_{_}ₑₓₜ) may add to a parasitic gate-to-drain capacitance (C_{gd2}) of the cascode FET (M₂). The capacitor may further substantially offset the distortion output of the FET amplifier (M₁) and the distortion output of the cascode FET (M₂).

The first equivalent impedance may substantially offset the distortion output of the FET amplifier (M₁) based upon the added inductor (L_{g2}) and the capacitor (C_{gd2}_{_}ₑₓₜ). The second equivalent impedance may substantially offset the distortion output of the cascode FET (M₂) based upon the added inductor (L_{g2}) and the capacitor (C_{gd2}_{_}ₑₓₜ). The capacitor may be a programmable variable capacitor. The distortion output of the FET amplifier (M₁) may be substantially offset by the first equivalent impedance, resulting in an improved value of an input third-order intermodulation intercept point (IIP3) of the FET amplifier (M₁). The output of the cascode FET (M₂) may be substantially offset by the second equivalent impedance, resulting in an improved value of an input third-order intermodulation intercept point (IIP3) of the cascode FET (M₂).

The IIP3 (in units of dBm) value may be improved by at least 3 dB. The IIP3 value may be improved by at least 6 dB. The distortion output of the FET amplifier (M₁) and the distortion output of the cascode FET (M₂) may be based upon the third-order nonlinearity coefficient (g₃). A first offset (g_{oB,M1}) associated with the first equivalent impedance may substantially offset the distortion output of the FET amplifier (M₁). A second offset (g_{oB,M2}) associated with the second equivalent impedance may substantially offset the distortion output of the cascode FET (M₂).

The proposed LNA (method and amplifier) may include a field-effect transistor (FET) amplifier (M₁) and a cascode FET (M₂). A capacitor (C_{gd2}_{_}ₑₓₜ) may be connected between the gate of the cascode FET (M₂) and a drain of the cascode FET (M₂). The capacitor (C_{gd2}_{_}ₑₓₜ) may add to a parasitic gate-to-drain capacitance (C_{gd2}_{_}ₑₓₜ) of the cascode FET (M₂). The capacitor (C_{gd2}_{_}ₑₓₜ.) may further substantially offset the distortion output of the FET amplifier (M₁). The cascode FET (M₂) may be in series with the FET amplifier (M₁). Each FET may operate with a respective third-order nonlinearity coefficient (g₃) and a respective linear gain (g₁). Each respective ratio (g₃/g₁) of the third-order nonlinearity coefficient (g₃) to the linear gain (g₁) may be positive. An inductor (L_{g2}) may be added at a gate of the cascode FET (M₂). The inductor (L_{g2}) may be operatively coupled with other components in a circuit which may result in a first equivalent impedance looking into an input of the cascode FET (M₂) from the FET amplifier (M₁). The first equivalent impedance may substantially offset a distortion output of the FET amplifier (M₁) based upon the added inductor (L_{g2}).

The proposed approach (and/or proposed LNA) may include a method of amplifying. At least the above-mentioned and below-mentioned steps/components, mentioned with regard the amplifier may also be applied to the method of amplifying. The method may operate a field-effect transistor (FET) amplifier (M₁) and/or a cascode FET (M₂). The cascode FET (M₂) may be in series with the FET amplifier (M₁) and/or an inductor at a gate of the cascode FET (M₂). Each FET may operate with a respective third-order nonlinearity coefficient (g₃) and a respective linear gain (g₁). Each respective ratio (g₃/g₁) of the respective third-order nonlinearity coefficient (g₃) to the respective linear gain (g₁) may be positive. An inductor (L_{g2}) may connected with other components in a circuit, which may result in a first equivalent impedance looking into an input (e.g., source terminal) of the cascode FET (M₂) from the FET amplifier (M₁). The first equivalent impedance may substantially offset a distortion output of the FET amplifier (M₁) based upon the added inductor (L_{g2}).

In the method of amplifying, the inductor (L_{g2}) with the other components in the circuit may further result in a second equivalent impedance looking out of the gate of the cascode FET (M₂). The second equivalent impedance may substantially offset a distortion output of the cascode FET (M₂) based upon the added inductor (L_{g2}).

In the method of amplifying, a capacitor (C_{gd2}_{_}ₑₓₜ) may be connected between the gate of the cascode FET (M₂) and a drain of the cascode FET (M₂). The capacitor (C_{gd2}_{_}ₑₓₜ.) may add to a parasitic gate-to-drain capacitance (C_{gd2}) of the cascode FET (M₂). The capacitor (C_{gd2}_{_}ₑₓₜ) may further substantially offset the distortion output of the FET amplifier (M₁).

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1A is a graph illustrating normalized second-order and third-order transconductance characteristics in a non-limiting example of an N-Channel Metal-Oxide Semiconductor (NMOS) device with width-to-length ratio, W/L=120/0.13 and drain to source voltage, V_{ds}=0.6 V.

FIG. 1B is a circuit diagram illustrating the proposed LNA.

FIG. 2 is a circuit diagram illustrating an example digitally-programmable capacitor (C_{gd2}_{_}ₑₓₜ), according to the proposed LNA.

FIG. 3 is a circuit diagram illustrating an example nonlinear small-signal model of the proposed LNA's input stage with Mₜ.

FIG. 4 is a circuit diagram illustrating an example nonlinear small-signal model of the proposed LNA's cascode stage with M₂.

FIG. 5 is a graph indicating calculation results of a third-order distortion measure |ε(Δω, 2ω)| for L_{g2} with three C_{gd2}_{_}ₑₓₜ. combinations in the cascode stage (with M₂) of the proposed LNA.

FIG. 6 is a graph indicating simulated voltage gains from Vᵢₙ, to V_{y} and V_{gs2} of the proposed LNA with and without L_{g2} and C_{gd2}_{_}ₑₓₜ (ideal components).

FIG. 7A is a circuit diagram illustrating an example simplified small-signal analysis model of the cascode stage for reverse isolation analysis, according to the proposed LNA.

FIG. 7B is a graph indicating simulated reverse isolation from Vₒᵤₜ_{_}_{LNA} to V_{y} with and without L_{g2}, according to the proposed LNA.

FIG. 8 is an image of a chip micrograph of the fabricated proposed LNA.

FIG. 9 is a graph indicating measured scattering parameters of the proposed LNA with buffer stage (−5.3 dB gain).

FIG. 10 is a graph illustrating an example measured noise figure of the proposed LNA with buffer stage (−5.3 dB gain).

FIG. 11A is a graph illustrating an example measured input IIP3 of the proposed LNA with buffer stage (−5.3 dB gain).

FIG. 11B is a graph illustrating an example output spectrum from a test with two tones at 1.8 GHz and 1.7995 GHz and an input power of −35 dBm, according to the proposed LNA.

FIG. 12 is a graph illustrating an example measured input-referred 1-dB compression point of the proposed LNA with buffer stage (−5.3 dB gain) at 1.8 GHz.

FIG. 13 is a graph illustrating an example IIP3 vs. C_{gd2}_{_}ₑₓₜ comparison (simulation vs. measurement results), according to the proposed LNA.

### DETAILED DESCRIPTION OF THE INVENTION

A description of example embodiments of the invention follows.

Requirements for portable electronic devices with low-power radio frequency (RF) circuits may be based on a need to extend battery lifetimes. The low-noise amplifier (LNA) may be a critical block in RF receiver front-ends because its specifications may strongly impact the system-level performance of the complete receiver, including overall noise and/or linearity. Over the past years, some subthreshold (and/or weak inversion) LNAs are reported to achieve lower power consumption (see for example, the following publications which are hereby incorporated by reference in their entirety herein: Do, A. V., Boon, C. C., Do, M. A., Yeo, K. S., and Cabuk, A., “A Subthreshold Low-Noise Amplifier Optimized for Ultra-Low-Power Applications in the ISM Band,” IEEE Trans. on Microwave Theory and Techniques, vol. 56, no. 2, pp. 286-292, February 2008, hereinafter “A Subthreshold Low-Noise Amplifier Optimized for Ultra-Low-Power Applications in the ISM Band;” Lee, H. and Mohammadi, S., “A 3GHz Subthreshold CMOS Low Noise Amplifier,” in Proc. Radio Frequency Integrated Circuit (RFIC) Symp., June 2006, hereinafter “A 3GHz Subthreshold CMOS Low Noise Amplifier;” Taris, T., Begueret, J., and Deval, Y., “A 60 μW LNA for 2.4 GHz Wireless Sensors Network Applications,” in Proc. Radio Frequency Integrated Circuit (RFIC) Symp., June 2011, hereinafter “A 60 μW LNA for 2.4 GHz Wireless Sensors Network Applications;” and Shameli, A. and Heydari, P., “A Novel Ultra Low Power Low Noise Amplifier Using Differential Inductor Feedback,” in Proc. IEEE European Solid State Circuit Conf. (ESSCIRC), pp. 352-355, June 2011, hereinafter “A Novel Ultra Low Power Low Noise Amplifier Using Differential Inductor Feedback”), which may be due to a higher transconductance-to-drain current ratio (g₁ₙ/I_{D}) and a lower power supply (V_{DD}). However, a prevalent design challenge associated with subthreshold LNAs may be linearity degradation. In subthreshold LNAs (“A Subthreshold Low-Noise Amplifier Optimized for Ultra-Low-Power Applications in the ISM Band,” “A 3GHz Subthreshold CMOS Low Noise Amplifier,” “A 60 μW LNA for 2.4 GHz Wireless Sensors Network Applications,” and “A Novel Ultra Low Power Low Noise Amplifier Using Differential Inductor Feedback”) the input third-order intermodulation intercept point (IIP3) may be less than −10 dBm.

Prevalent third-order intermodulation intercept point (IIP3) improvement methods for low-power LNAs in narrowband applications may include two approaches related to the proposed approach. The first approach may use an auxiliary transistor biased in the weak inversion region to cancel the third-order nonlinearity coefficient (g₃), but in such an approach, the main transistor may be operated in a strong inversion region with higher linear transconductance (g₁=gₘ) than in the auxiliary path (see for example, “Linearization of CDMA Receiver Front-Ends,” and “Modified Derivative Superposition Method for Linearizing FET Low-Noise Amplifier”). The second approach may operate the main transistor between the moderate inversion and subthreshold regions for finding the optimum bias zone (see for example, “MOST Moderate-Weak-Inversion Region as the Optimum Design Zone for CMOS 2.4-GHz CS-LNAs”). However, existing linearization methods do not report measurements of radio frequency (RF) amplifiers using main transistors biased in the subthreshold region without use of auxiliary transistors.

The proposed LNA may include a subthreshold RF circuit (see for example, the following publications that are hereby incorporated by reference in their entirety herein: Chang, C.-H. and Onabajo, M., “Linearization of Subthreshold Low-Noise Amplifiers,” in Proc. IEEE Intl. Conf. on Circuits and Systems (ISCAS), pp. 377-380, May 2013, hereinafter “Linearization of Subthreshold Low-Noise Amplifiers;” Chang, C.-H. and Onabajo, M., “IIP3 Enhancement of Subthreshold Active Mixers,” IEEE Trans. on Circuits and System II: Express Briefs, vol. 60, no. 11, pp. 731-735, Nov. 2013, hereinafter “IIP3 Enhancement of Subthreshold Active Mixers;” and Chang, C.-H. and Onabajo, M., “Input Impedance Matching Optimization for Adaptive Low-Power Low-Noise Amplifiers,” Analog Integrated Circuits and Signal Processing, vol. 77, no. 3, pp. 583-592, December 2013, hereinafter “Input Impedance Matching Optimization for Adaptive Low-Power Low-Noise Amplifiers”), different characteristics for transistors biased in subthreshold may be identified, and may include but are not limited to:

1.) Higher power efficiency: transistors biased in subthreshold region may provide a higher gₘ/I_{D} ratio than those biased in the strong inversion region. Furthermore, the drain-to-source voltage (V_{DS}) may be lower in the subthreshold region, which may permit the use of lower power supply voltages.

2.) The change of the contribution and increase of parasitic capacitances: in the subthreshold region, the gate-to-source capacitance (C_{gs}) may no longer dominate, implying that the gate-to-drain capacitance (C_{gd}) and/or the gate-to-bulk capacitance (C_{gb}) may be taken into account for more sophisticated design. Moreover, to achieve similar transconductance gains as in the strong inversion region, it may be preferably required to increase the transistor widths, which may result in higher parasitic capacitances and/or lower transition frequency (f_{T}).

3.) Linearity degradation due to highly positive g₃/g₁: in the proposed LNA, the sign of g₃ may change from negative to positive when the transistor biasing is changed from strong inversion to subthreshold (see for example, “Linearization of Subthreshold Low-Noise Amplifiers”). In addition, the value of g₃/g₁ may preferably depend on the gₘ/I_{D} ratio when biasing transistors in the subthreshold region.

Measurement results are presented herein for the proposed subthreshold LNA linearization technique (the proposed LNA) that preferably uses passive devices (and/or preferably does not use non-passive devices) for the third-order nonlinear coefficient cancellation without additional power consumption. Furthermore, a digitally programmable IIP3 tuning topology is introduced herein that may be applied in RF front-end calibration methods (see for example, the following publications which are hereby incorporated by reference in their entirety herein: Chauhan, H., Choi, Y., Onabajo, M., Jung, I.-S. and Kim, Y.-B., “Accurate and Efficient On-Chip Spectral Analysis for Built-In Testing and Calibration Approaches,” IEEE Trans. on Very Large Scale Integration (VLSI) Systems, vol. 22, no. 3, pp. 497-506, March 2014, hereinafter “Accurate and Efficient On-Chip Spectral Analysis for Built-In Testing and Calibration Approaches;” and Choi, Y., Chang, C.-H., Chauhan, H., Jung, I.-S., Onabajo, M. and Kim, Y.-B., “A Built-In Calibration System to Optimize Third-Order Intermodulation Performance of RF Amplifiers,” in Proc. IEEE Intl. Midwest Symp. on Circuits and Systems (MWSCAS), pp. 599-602, Aug. 2014, hereinafter “A Built-In Calibration System to Optimize Third-Order Intermodulation Performance of RF Amplifiers”). Analyses of linearity, gain, noise, and input matching conditions for the proposed linearized subthreshold LNA are presented to follow. Chip measurement results are also presented to follow.

An LNA may include existing LNA linearization methods (see for example the following publication, which is hereby incorporated by reference in its entirety herein, Zhang, H. and Sanchez-Sinencio, E., “Linearization Techniques for CMOS Low Noise Amplifiers: A Tutorial,” IEEE Trans. Circuits and Systems I: Regular Papers, vol. 58, no. 1, pp. 22-36, January 2011, hereinafter “Linearization Techniques for CMOS Low Noise Amplifiers: A Tutorial”), in which the main transistors may be biased in strong inversion. In some existing approaches (see for example, “Modified Derivative Superposition Method for Linearizing FET Low-Noise Amplifier”), g₁ and g₃ (i.e., the linear gain and third-order nonlinearity coefficient) may have opposite signs when CMOS transistors are operated in strong inversion, while g₁ and g₃ may have the same sign when transistors are operated in the subthreshold region. Thus, novel linearization techniques may be desired for subthreshold LNAs due to the potentially differing polarity of g₃. As such, g₁ and g₃ may both have the same sign (both having a negative sign and/or both having a positive sign), in order to preferably operate in the subthreshold and/or weak inversion regions, in which the ratio of g₁ to g₃ may preferably be positive.

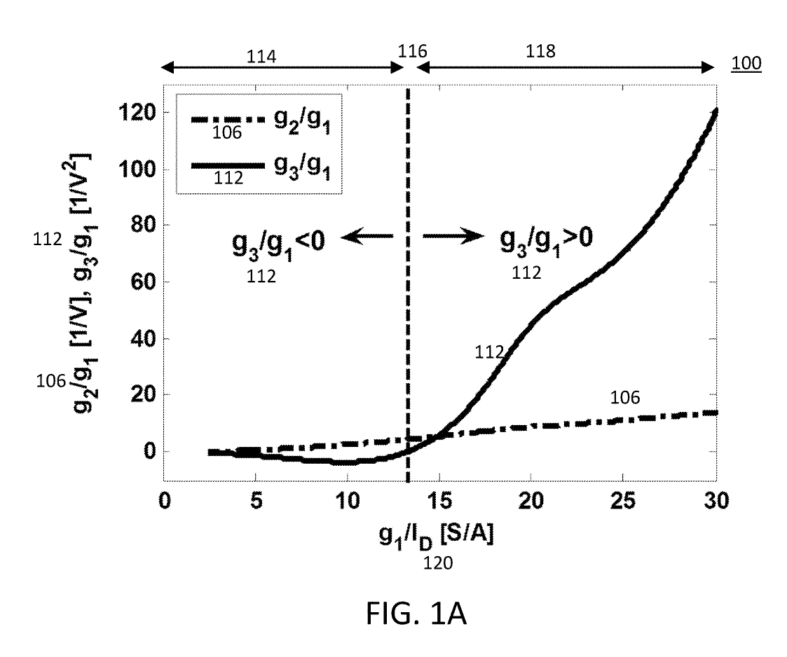

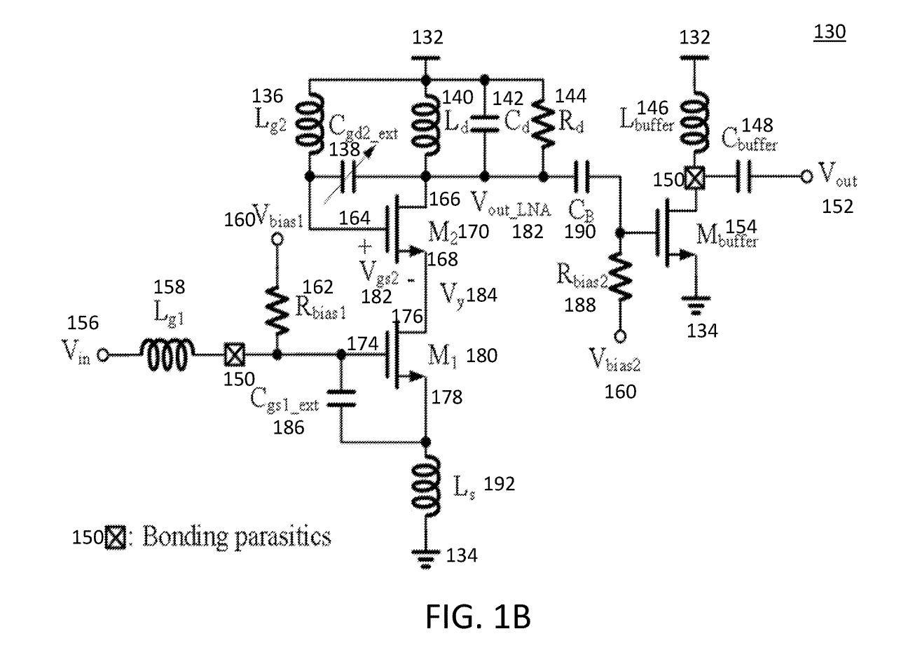

FIG. 1A shows a graph 100 of the normalized second-order (g₂) and third-order transconductance (g₃) characteristics (106, 112, respectively) of an NMOS transistor, where g₂ and/or g₃ may be divided by the linear transconductance g₁. In particular, FIG. 1A is a graph illustrating normalized second-order and/or third-order transconductance characteristics (in a non-limiting example of an NMOS device with width-to-length ratio, W/L=120/0.13 μm and drain to source voltage, V_{ds}=0.6 V).

FIG. 1A illustrates that the g₂/g₁ ratio 106 may have a sign that may preferably be positive (above the value zero on the x-axis, namely the gₘ/I_{D} ratio 120), but the sign of the g₃/g₁ ratio 112 preferably depends on the mode of operation (including but not limited to modes of strong inversion 114, weak inversion (at and/or around) 116, and/or subthreshold 118). In the proposed LNA, in the subthreshold region 118 (and/or weak inversion region 116), the ratio of g₃/g₁ (112) may preferably be positive and its value may preferably depend on the gₘ/I_{D} ratio (120).

FIG. 1B shows a schematic of the proposed LNA 130, where inductor L_{g2} (136) and/or digitally-programmable capacitor C_{gd2}_{_}ₑₓₜ (138) may improve the IIP3. In other words, FIG. 1B is a circuit diagram illustrating a proposed linearized subthreshold LNA. Inductor L_{g1} (158), inductor L_{buffer} (146), and capacitor C_{buffer} (148) may be off-chip components for impedance matching purposes.

As illustrated in FIG. 1B, the proposed LNA may include a transistor M₁ (180) having gate (174), source (178) and drain (176) may be connected in series with a transistor M₂ (170) having gate (164), source (168) and drain (166). The transistor M₁ (180) may connect to a bias resistance R_{bias1} (162) having a corresponding bias voltage V_{bias1} (160). The transistor M₁ (180) may have an associated on-chip inductance Lₛ (192) and gate-to-source capacitance C_{gs1}_{_}ₑₓₜ (186). As illustrated in FIG. 1B, the transistor M₂ (170) may have a gate-source voltage V_{gs2} (182) and source voltage V_{y} (184). An input voltage V₁ (156) may drive the gate (174) of M₁ (180) through an inductor L_{g1} (158). As illustrated in FIG. 1B, the transistor M₂ (170) may connect to a standard RLC load tank, which may include, but is not limited to include inductance L_{d} (140), capacitance C_{d} (142), and/or resistance R_{d} (144).

As illustrated in FIG. 1B, for the proposed LNA, the output voltage V_{out LNA} (182) of transistor M₂ (170) may feed into a buffer stage circuit that includes buffer transistor M_{buffer} (154). Circuitry associated with the buffer transistor M_{buffer} (154) may include a capacitor C_{B} (190), bias resistor R_{bias2} (188) having a bias voltage V_{bias2} (160), inductor L_{buffer} (146), and capacitor C_{buffer} (148) may have an output voltage Vₒᵤₜ (152). Also as illustrated in FIG. 1B, the proposed LNA may include bonding parasitics 150, power connections 132, and ground connections 134.

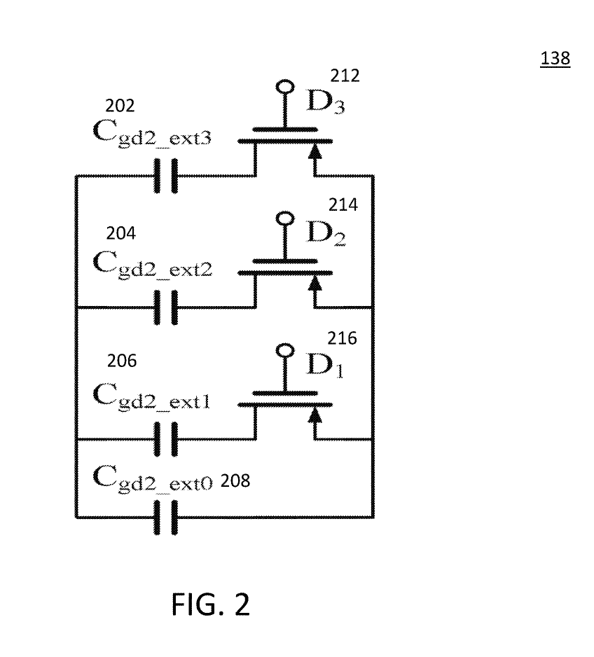

FIG. 2 is a circuit diagram illustrating an example digitally-programmable capacitor (C_{gd2}_{_}ₑₓₜ, element 138), according to the proposed LNA. According to the proposed LNA, as illustrated in FIG. 2, C_{gd2}_{_}ₑₓₜ. (138) may be implemented with a fixed metal-insulator-metal (MIM) capacitor C_{gd2}_{_}ₑₓₜ₀ (208) and/or a 3-bit digitally-programmable MIM capacitor using capacitors C_{gd2}_{_}ₑₓₜ₁ (206), C_{gd2}_{_}ₑₓₜ₂ (204), and C_{gd2}_{_}ₑₓₜ₃ (202) and using FET switches 212, 214, and 216. Metal-Oxide Semiconductor (MOS) capacitors may also be employed to realize C_{gd2}_{_}ₑₓₜ, but may result in slightly increased LNA gain variation and may have less linearity improvement compared to metal-insulator-metal capacitors.

In the proposed LNA, the bonding/package parasitics and “buffer stage” of FIG. 1B (also referred to as “buffer” herein) may be neglected to simplify the small-signal analysis. The proposed LNA may use one approach (see for example the following publication, which is hereby incorporated by reference in its entirety herein, Lavasani, S. H. M. and Kiaei, S., “A New Method to Stabilize High Frequency High Gain CMOS LNA,” in Proc. IEEE Intl. Conf. on Electronics, Circuits and Systems (ICECS), vol. 3, pp. 982-985, December 2003, hereinafter “A New Method to Stabilize High Frequency High Gain CMOS LNA”) in which an inductor being added between the gate of the cascode transistor and the power supply may improve stability of a common-source cascode LNA by creating a potentially sharp notch in the transfer function of the reverse isolation (S12) around the operating frequency. An LNA may also apply other methods (see for example the following publication, which is hereby incorporated by reference in its entirety herein, Fan, X., Zhang, H., and Sánchez-Sinencio, E., “A Noise Reduction and Linearity Improvement Technique for a Differential Cascode LNA,” IEEE J. Solid-state Circuits, vol. 43, no. 3, pp. 588-599, March 2008, hereinafter “A Noise Reduction and Linearity Improvement Technique for a Differential Cascode LNA”), in which a fully differential common-source LNA topology with an inductor at the gate of the cascode transistor and a cross-coupling capacitor between the gate of the cascode transistor and the source of the opposite cascode transistor may decrease the noise figure, which may improve the linearity and/or enhance the voltage gain. However, in existing approaches, the LNA may be biased in the strong inversion region. By contrast, the proposed approach may be biased in the weak inversion region (and/or subthreshold region). The proposed approach may include a linearization method (and/or amplifier) for subthreshold common-source cascode LNAs that may preferably not require cross-coupling for nonlinearity cancellation.

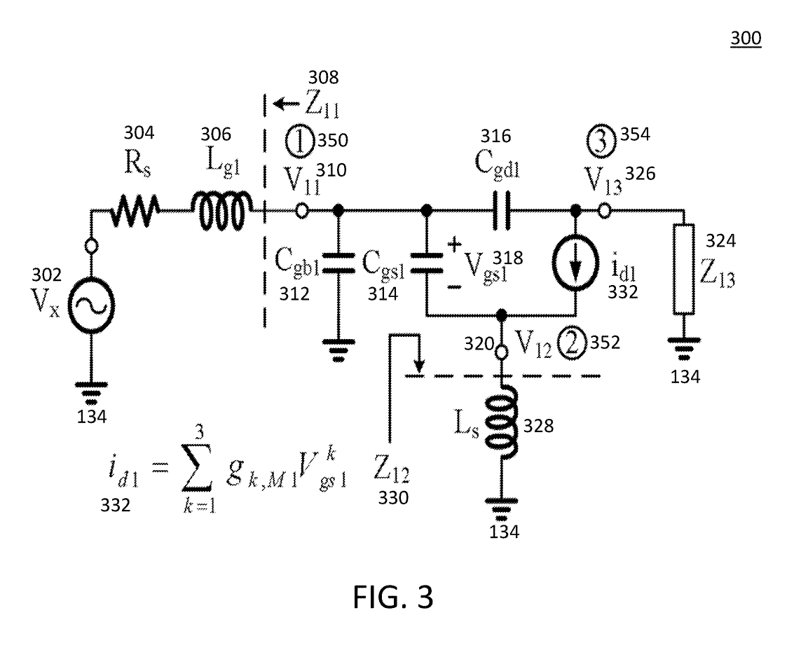

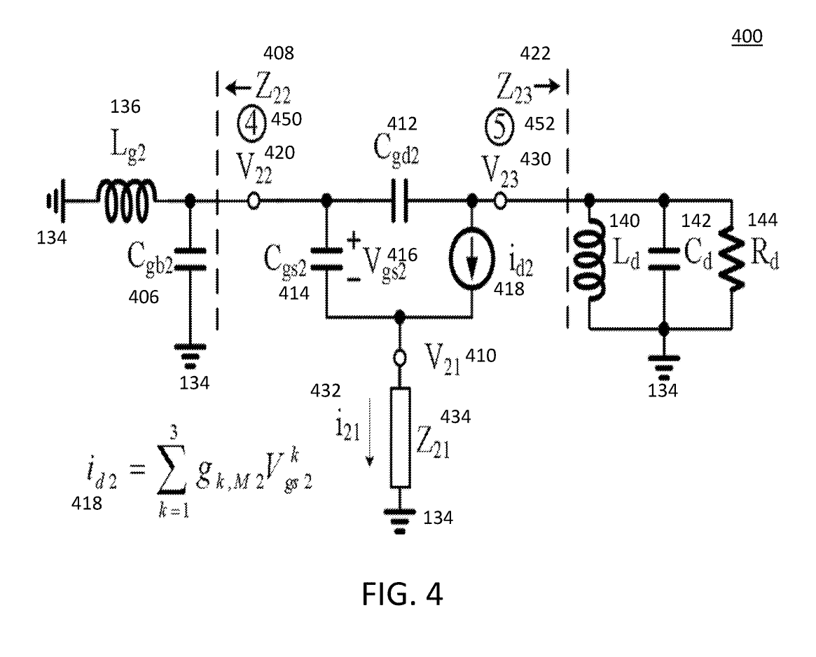

Linearity Analysis. The following shows an analysis of the proposed LNA (130 of FIG. 1B). The analysis of the input stage of transistor M₁ (180 of FIG. 1B), and an analysis of the cascode stage of transistor M₂ (170 of FIG. 1B) may be performed separately, as illustrated in FIG. 3, and FIG. 4, respectively, and also in Equations (1) through (14) to follow.

FIG. 3 shows the nonlinear small-signal model 300 of the input stage of the proposed LNA where the extra metal-insulator-metal capacitor C_{gst ext} may be included in the parasitic capacitance C_{gs1} (314) which may have an associated voltage V_{gs1} (318). In the proposed LNA, the IIP3 of transistor M₁ (180 of FIG. 1B) may be derived after Volterra series analysis (see for example, “Linearization of CDMA Receiver Front-Ends,” “Modified Derivative Superposition Method for Linearizing FET Low-Noise Amplifier,” and “A Noise Reduction and Linearity Improvement Technique for a Differential Cascode LNA”) as:

$${IIP}_{3 , M 1} = \frac{1}{6 {R}_{s} \cdot \vert {H}_{1} ( ω ) \vert \cdot {\vert {A}_{11} ( ω ) \vert}^{3} \cdot \vert {ɛ}_{M 1} ( Δ ω , 2 ω ) \vert} , \qquad ( 1 )$$

where ω may be the center frequency of the two intermodulation tones at ω_{RF1} and ω_{RF2}, Δω is defined as |ω_{RF1}-ω_{RF2}|, and Rₛ is the antenna impedance of son. Referring to FIG. 1B and FIG. 3, H₁(ω) may be the third-order nonlinearity transfer function from V₁(156 of FIG. 1B) to the drain-source current (i_{d1}, 332 of FIG. 3) of M₁ (180 of FIG. 1B). The drain-source current i_{d1} (332 of FIG. 3) may be derived according to Equation (A.7) to follow. A₁₁(ω) may be the linear transfer function from the input voltage V_{X} (302 of FIG. 3) to the gate-to-source voltage V_{gs1} (318 of FIG. 3), and εₘ₁(Δω, 2ω) may represent the nonlinear contribution from the second-order and third-order terms of transistor M₁ (180 of FIG. 1B). The nonlinear small-signal model 300 of FIG. 3 may also include a source resistance Rₛ (304), inductance L_{g1} (306), voltage V₁₁ (310) at node 1 (350), voltage V₁₂ (320) at node 2 (352), voltage V₁₃ (326) at node 3 (354), gate-to-drain capacitance C_{gd1} (316), capacitance C_{gb1} (312), inductance Lₛ (328), and/or ground connections (134). In the small-signal model 300, impedances Z₁₁ (308), Z₁₂ (330), and Z₁₃ (324) may be derived according to the following Equations (6), (7), and (8), respectively. As illustrated below, minimization of the term |ε_{M1}(Δω,2ω| in Equation (1) may lead to improved IIP₃. For this reason, the analysis of the ε(Δω,2ω) term for transistors M₁ (180) and M₂ (170) is shown to follow. The ε_{M1}(Δω,2ω) term of M₁ may be expressed as:

$$\begin{matrix} {ɛ}_{M 1} ( Δ ω , 2 ω ) = {g}_{3 , M 1} - {g}_{oB , M 1} , where \text{:} & ( 2 ) \\ {g}_{oB , M 1} = \frac{2}{3} {g}_{2 , M 1}^{2} [ \frac{2}{{g}_{1 , M 1} + {g}_{M 1} ( Δ ω )} + \frac{1}{{g}_{1 , M 1} + {g}_{M 1} ( 2 ω )} ] , & ( 3 ) \\ {g}_{M 1} ( ω ) = \frac{\begin{matrix}\begin{matrix}1 + j ω {C}_{gd 1} \cdot [ {Z}_{11} ( ω ) + {Z}_{13} ( ω ) ] + \\ j {ωC}_{gs 1} \cdot [ {Z}_{11} ( ω ) + {Z}_{12} ( ω ) ] +\end{matrix} \\ j ω {C}_{gb 1} \cdot [ 1 + j ω {C}_{gd 1} {Z}_{13} ( ω ) ] \cdot {Z}_{11} ( ω )\end{matrix}}{Z ( ω )} , & ( 4 ) \\ Z ( ω ) = {Z}_{12} ( ω ) + j ω {C}_{gb 1} [ 1 + j ω {C}_{gd 1} {Z}_{13} ( ω ) ] {Z}_{11} ( ω ) {Z}_{12} ( ω ) + j ω {C}_{gd 1} [ {Z}_{11} ( ω ) {Z}_{12} ( ω ) + {Z}_{11} ( ω ) {Z}_{13} ( ω ) + {Z}_{12} ( ω ) {Z}_{13} ( ω ) ] , & ( 5 ) \\ {Z}_{11} ( ω ) = {R}_{s} + j ω {L}_{g 1} , & ( 6 ) \\ {Z}_{12} ( ω ) = j ω {L}_{s} , & ( 7 ) \\ {Z}_{13} ( ω ) = \frac{\begin{matrix}1 + j ω {C}_{gd 2} {Z}_{23} ( ω ) + \\ [ j ω {C}_{gs 2} + j ω {C}_{gd 2} - {ω}^{2} {C}_{gs 2} {C}_{gd 2} {Z}_{23} ( ω ) ] \cdot {Z}_{22} ( ω )\end{matrix}}{\begin{matrix}{g}_{1 , M 2} + j ω {C}_{gs 2} + \\ [ j ω {C}_{gd 2} {g}_{1 , M 2} + {ω}^{2} {C}_{gd 2} {G}_{gs 2} ] \cdot [ {Z}_{22} ( ω ) + {Z}_{23} ( ω ) ]\end{matrix}} , & ( 8 ) \\ {Z}_{22} ( ω ) = ( j ω {L}_{g 2} ) // {( j ω {C}_{gb 2} )}^{- 1} , & ( 9 ) \\ {Z}_{23} ( ω ) = {R}_{d} // ( j ω {L}_{d} ) // {( j ω {C}_{d} )}^{- 1} . & ( 10 )\end{matrix}$$

The proposed LNA may be different than existing approaches (see for example, “Linearization of Subthreshold Low-Noise Amplifiers”), in that the parasitic capacitance C_{gb1} (312) may be included above for the proposed LNA to further improve the accuracy of the analysis, for which more detailed derivations are included in Appendix A to follow. The variables g_{1,M1}, g_{2,M1} and g_{3,M1} are the linear gain, second-order nonlinearity coefficient, and third-order nonlinearity coefficient of transistor M₁ (180), respectively.

FIG. 4 illustrates a nonlinear small-signal model 400 that may be included in the proposed LNA. The nonlinear small-signal model 400 of the cascode stage (FIG. 4) of transistor M₂ (170 of FIG. 1B) may have an extra MIM capacitor C_{gd2}_{_}ₑₓₜ. (138 of FIG. 1B) which may be merged with the parasitic capacitance C_{gd2} (412 of FIG. 4). In other words, FIG. 4 is a circuit diagram illustrating an example nonlinear small-signal model of the proposed LNA's cascode stage with M₂. The drain-source current i_{d2} (418) may be derived according to Equation (B.7) to follow. A₂₁(w) may be the linear transfer function corresponding to the gate-to-source voltage V_{gs2} (416 of FIG. 4), and ε_{M2}(Δω, 2ω) may represent the nonlinear contribution from the second-order and third-order terms of transistor M₂ (170 of FIG. 1B). The nonlinear small-signal model 400 of FIG. 4 may also include an inductance L_{g2} (136), voltage V₂₂ (420) at node 4 (450), voltage V₂₃ (430) at node 5 (452), an impedance Z₂₁ (434) having a corresponding voltage V₂₁ (410) and current i₂₁ (432), an impedance Z₂₂ (408) derived by Equation (9) above, an impedance Z23 (422) derived by Equation (10) above, gate-to-source capacitance C_{gs2} (414), gate-to-drain capacitance C_{gd2} (412), capacitance C_{gb2} (406), and/or ground connections (134). The small-signal model 400 may include inductance L_{d} (140), capacitance C_{d} (142), and/or resistance R_{d} (144).

Referring back to FIG. 1B of the proposed LNA, a cascode device whose gate is connected to an AC ground may have a small impact on the overall linearity of a cascode common-source LNA. On the other hand, the cascode stage with additional components at the gate 164 of M₂ (170) may have a significant (e.g., substantial) impact on the overall linearity performance. Subthreshold RF designs may employ wide transistors to achieve sufficiently high transconductances. Hence, increasing the width/length ratio of M₂ (170) may not be a feasible option to reduce its impact on linearity because the adverse effects of the parasitic capacitances on gain and reverse isolation may become worse. However, nonlinearity cancellation in the cascode stage may be realized with the proposed LNA to improve third-order linearity. The following equations may provide insights into the linearity effect of the cascode device. Unlike existing approaches, the proposed LNA may include an analysis (shown to follow) for the subthreshold topology in FIG. 1B. By using Volterra series analysis (see for example, “A Noise Reduction and Linearity Improvement Technique for a Differential Cascode LNA”), the Aᵤᵣₐ of transistor M₂ (170) of the proposed LNA may be derived as:

$${A}_{IIP 3 , M 2}^{2} = \frac{4}{3} \cdot \frac{1}{\vert {H}_{2} ( ω ) \vert \cdot {\vert {A}_{21} ( ω ) \vert}^{3} \cdot \vert {ɛ}_{M 2} ( Δ ω , 2 ω ) \vert} . \qquad ( 11 )$$

The definition of ε_{M2}(Δω,2ω) may be the same as in Equation (2) and may be rewritten as:

$$\begin{matrix} {ɛ}_{M 2} ( Δ ω , 2 ω ) = {g}_{3 , M 2} - {g}_{oB , M 2} , where \text{:} & ( 12 ) \\ {g}_{oB , M 2} = \frac{2}{3} {g}_{2 , M 2}^{2} [ \frac{2}{{g}_{1 , M 2} + {g}_{M 2} ( Δ ω )} + \frac{1}{{g}_{1 , M 2} + {g}_{M 2} ( 2 ω )} ] , & ( 13 ) \\ {g}_{M 2} ( ω ) = \frac{\begin{matrix}\begin{matrix}1 + j ω {C}_{gd 2} {Z}_{23} ( ω ) + \\ ( j ω {C}_{gs 2} + j ω {C}_{gd 2} ) \cdot [ 1 + j ω {C}_{gd 2} {Z}_{23} ( ω ) ] \cdot {Z}_{22} ( ω ) +\end{matrix} \\ {ω}^{2} {C}_{gs 2} {C}_{gd 2} {Z}_{22} ( ω ) {Z}_{23} ( ω )\end{matrix}}{j ω {C}_{gd 2} {Z}_{22} ( ω ) {Z}_{23} ( ω )} . & ( 14 )\end{matrix}$$

The linear transfer function A₁₁(ω) in Equation (11) may be derived in Appendix B as Equation (B.9) to follow. Parameters g_{1,M2}, g_{2,M2} and g_{3,M2} are the linear gain, second-order nonlinear coefficient and third-order nonlinear coefficient of M₂ (170), respectively.

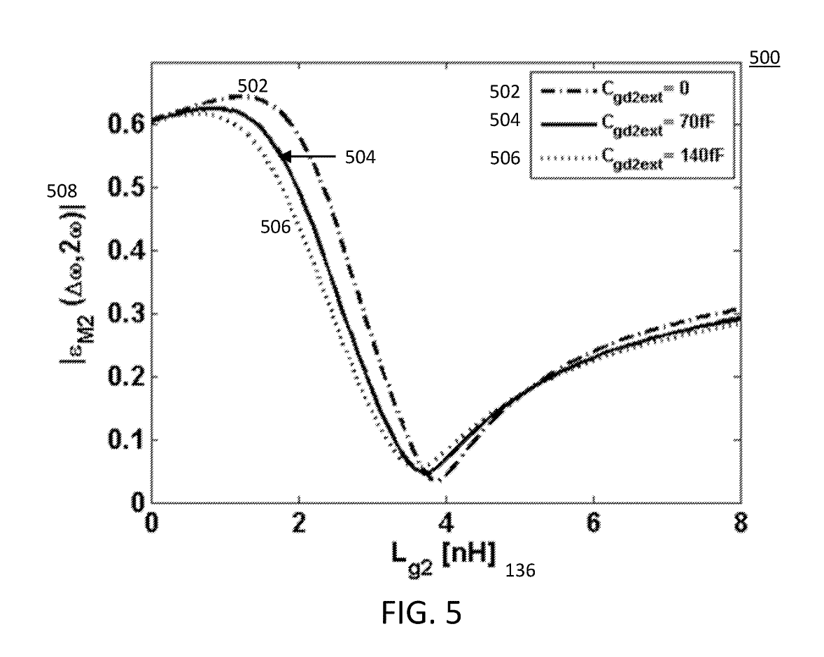

FIG. 5 is a graph indicating calculation results of a second-order and a third-order distortion measure |ε(Δω,2ω)| for L_{g2} (136 of FIG. 1B) with three C_{gd2}_{_}ₑₓₜ. (138 of FIG. 1B) combinations in the cascode stage (with M₂) of the proposed LNA (130 of FIG. 1B). FIG. 5 visualizes (500) the numerical calculations of |ε_{M2}(Δω,2ω)| (508) from Equation (12) versus L_{g2} (136 of FIG. 1B) for three values 502, 504, 506 of C_{gd2}_{_}ₑₓₜ (138 of FIG. 1B) based on the above equations. In the proposed LNA, a value of L_{g2} (136 of FIG. 1B) at (and/or around) 3.5 nH may lead to an optimum IIP3. In addition to the cancellations associated with Equations (12) and (2) for the cascode stage and input stage respectively, the effectiveness of the linearization may be affected by higher-order nonlinearities and interactions between the stages. The above equations may provide a foundation for the proposed LNA to identify tradeoffs based on key parameters. In practice, a designer may select a C_{gd2}_{_}ₑₓₜ (138 of FIG. 1B) value and sweep L_{g2} (136 of FIG. 1B) in post-layout circuit simulations using the proposed LNA with accurate device models and extracted parasitics. A standard IIP3 metric may be monitored during the simulations in lieu of the |ε_{M2}(Δω, 2ω)| term. The related reverse isolation (S12) and stability aspects for the selection of values of L_{g2} (136 of FIG. 1B) and C_{gd2}_{_}ₑₓₜ. (138 of FIG. 1B) values are described further to follow.

Voltage Gain. The voltage gain of the proposed LNA (and/or proposed linearized LNA) may be separated to identify the contributions associated with the transistors M₁ (180) and M₂ (170). In Appendices A and B to follow, the linear transfer functions from Vₓ to V₁₃ (FIGS. 3, 302 and 326, respectively) and from V₂₁ to V₂₃ (FIGS. 4, 410 and 430) are derived, which may represent the frequency-dependent voltage gains C₁₁(ω) and C₂₁(ω), respectively, of the two stages. From Equations (A.10) and (B.10) to follow, these voltage gains may be combined to determine the overall LNA gain:

Av(ω)=|C₁₁(ω)|×|C²¹(ω)|, Av(ω)=|C₁₁(ω)|×|C₂₁(ω)|. (15)

In addition to the nonlinearity cancellation analyzed above, a secondary mechanism may lead to linearity enhancement due to the extra components at the gate of M₂ (170 of FIG. 1B) of the proposed LNA.

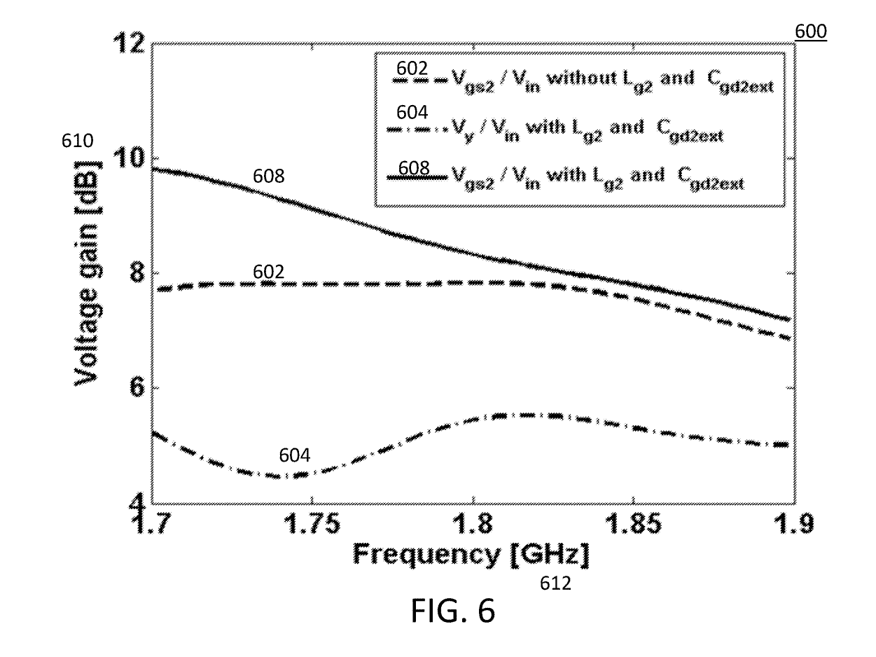

According to the proposed LNA, FIG. 6 displays 600 the following simulated voltage gains (610) versus frequency (612): the voltage gain from V₁ to V_{y} (604); the voltage gain from V₁ to V_{gs2} with L_{g2} and C_{gd2}_{_}ₑₓₜ (608); and the voltage gain from V₁ to V_{gs2} without L_{g2} and C_{gd2}_{_}ₑₓₜ. (602). In other words, FIG. 6 is a graph indicating simulated voltage gains 610 from V₁ to V_{y} and V_{gs2} of the proposed LNA with and without L_{g2} and C_{gd2}_{_}ₑₓₜ (referring to 604, 608, and 602, respectively). For the proposed LNA without L_{g2}, the voltage gain from Vᵢₙ to V_{y} (604) may be the same as the voltage gain from Vᵢₙ to V_{gs2} (602) but with opposite phase. The proposed LNA with L_{g2}=3.5 nH and C_{gd2}_{_}ₑₓₜ=150 fF may have a lower voltage gain V_{y}/Vᵢₙ, (604) than the conventional cascode common-source LNA, but both LNAs (or one or more LNAs) may have a similar V_{gs2}/V, gain (602, 608) for frequencies around and above the operating frequency (including, but not limited to, a 1.8 GHz operating frequency, and/or other operating frequencies). Hence, the attenuation at V_{y} (184 of FIG. 1B) and/or reduced signal swing at the corresponding node (168 of FIG. 1B) due to L_{g2} (136 of FIG. 1B) and C_{gd2}_{_}ₑₓₜ (138 of FIG. 1B) may contribute to the linearity improvement of the proposed LNA.

Input Matching Network. For the proposed LNA, the input matching of a subthreshold common-source LNA may be analyzed (see for example “Input Impedance Matching Optimization for Adaptive Low-Power Low-Noise Amplifiers”) without the inductor L_{g2} (136 of FIG. 1B). For the proposed LNA (with linearization) presented herein, it is shown below that the input impedance under consideration of the extra components may be estimated (and/or calculated) as:

$$\begin{matrix}{Z}_{in} ( ω ) = j ω {L}_{g 1} + {Z}_{in}^{*} ( ω ) // \frac{1}{j ω {C}_{MF}} ; where \text{:} & ( 16 ) \\ {Z}_{in}^{*} ( ω ) = \frac{1}{j ω {C}_{g s 1}} + j ω {L}_{s} + \frac{{g}_{1 , M 1} {L}_{s}}{{C}_{gs 1}} , & ( 17 ) \\ {C}_{MF} = ( 1 - A ( ω ) ) \cdot {C}_{gd 1} + {C}_{gb 1} , & ( 18 ) \\ A ( ω ) = {G}_{1 , M 1 - eff} ( ω ) \cdot {Z}_{13} ( ω ) , & ( 19 ) \\ {G}_{1 , M 1 - eff} ( ω ) = \frac{{g}_{1 , M 1}}{1 + j ω {L}_{s} ( {g}_{1 , M 1} + j ω {C}_{gs 1} )} - j ω {C}_{gd 1} , & ( 20 )\end{matrix}$$

and Z₁₃(ω) may be defined above in Equation (8).

Noise. According to the proposed LNA, a noise factor analysis for a subthreshold common-source LNA with inductive source degeneration (see for example, the following publication which is hereby incorporated by reference in its entirety herein, Yang, J., Tran, N., Bai, S., Fu, M., Skafidas, E., Halpern, M., Ng, D.C. and Mareels, I., “A Subthreshold Down Converter Optimized for Super-Low-Power Applications in MICS Band,” in Proc. IEEE Biomedical Circuits and Systems Conf. (BioCAS), pp. 189-192, November 2011) may result in:

$$F = 1 + {C}_{t}^{2} \times \frac{{ω}_{o}^{2} {R}_{s} γ {n}^{2} {V}_{T}}{{I}_{D}} [ \frac{δ {α}^{2}}{5 γ} ( 1 + {Q}_{in}^{2} ) \frac{{C}_{gs 1}}{{C}_{t}^{2}} + 1 - 2 \vert c \vert \frac{{C}_{gs 1}}{{C}_{t}} \sqrt{\frac{δ {α}^{2}}{5 γ}} ] , \qquad ( 21 )$$

where Cₜ=C_{gs1}+C_{gs1}_{_}ₑₓₜ, ω₀ may represent the operating frequency, γ and δ may represent the channel and/or gate noise coefficients, α=g_{1,M1}/g_{d0,M1}, g_{d0,M1} may represent the channel conductance with zero drain-source voltage, V_{T} may represent the thermal voltage, Qᵢₙ may represent the quality factor of the input matching network, and c may represent the correlation parameter between the gate and channel noise currents.

Reverse Isolation and Stability. Compared to conventional common-source cascode LNAs, the proposed LNA may preferably require an inductor at the gate of the cascode transistor. In the proposed LNA, the reverse isolation may be improved (see for example, “A New Method to Stabilize High Frequency High Gain CMOS LNA”) in a desired frequency band by sizing of the inductor at the gate of the cascode transistor.

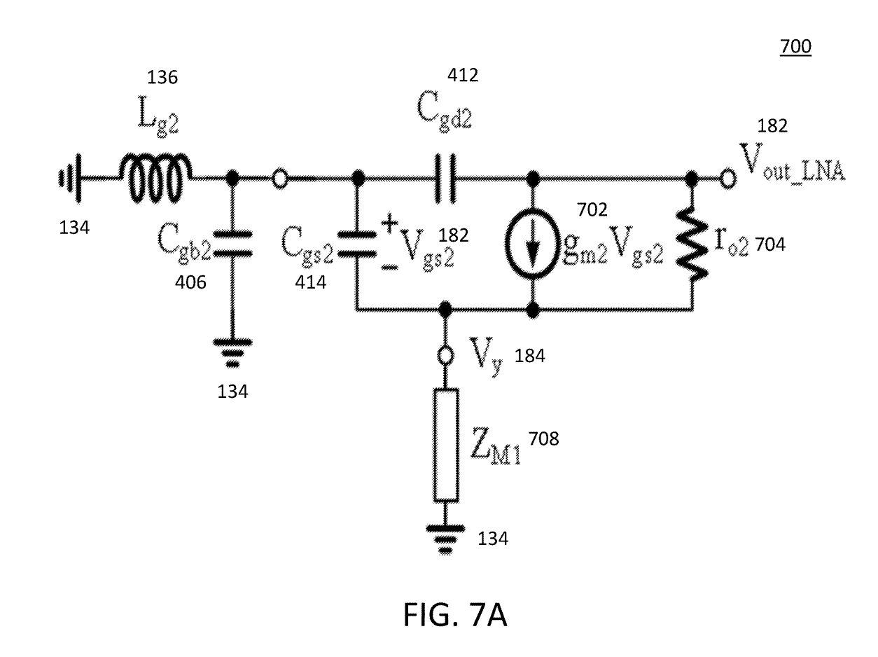

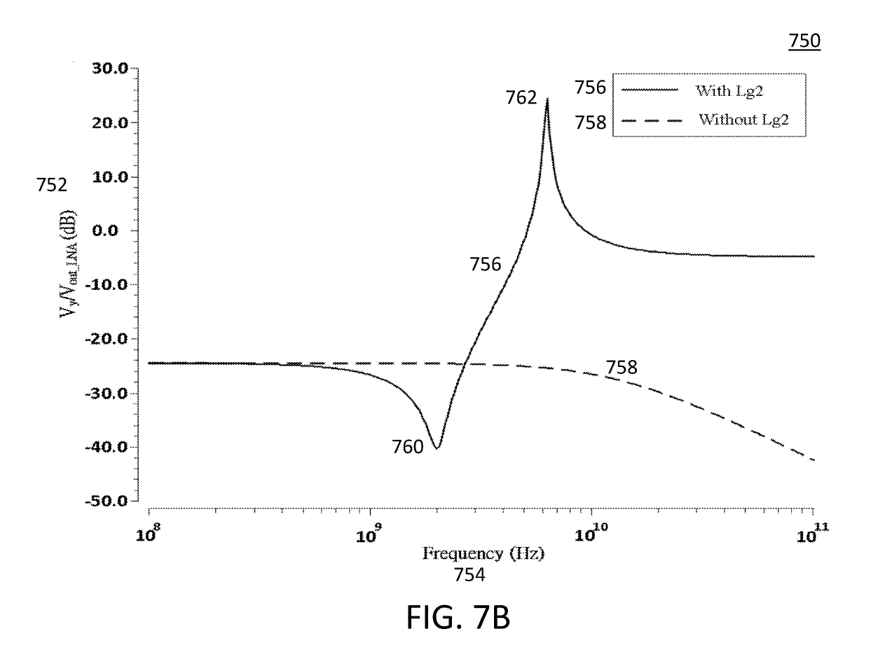

FIG. 7A is a circuit diagram of the proposed LNA that illustrates an example simplified small-signal analysis model of the cascode stage for reverse isolation analysis. To analytically estimate the impact on reverse isolation, the transfer function from Vₒᵤₜ_{_}_{LNA} (182) to V_{y} (184) in FIG. 1B may be derived from the small-signal circuit 700 in FIG. 7A:

$$H ( s ) = \frac{{V}_{y}}{{V}_{out \_ LNA}} = \frac{{s}^{3} + {b}_{2} {s}^{2} + {b}_{0}}{{a}_{3} {s}^{3} + {a}_{2} {s}^{2} + {a}_{1} s + {a}_{0}} , \qquad ( 22 )$$

where:

a₃=1+C_{gb2}/C_{gd2},

a₂=(rₒ₂+Z_{M11}+gₘ₂rₒ₂Z_{M1})/(C_{gs2}rₒ₂Z_{M1})+(rₒ₂+Z_{M1})/(C_{gd2}rₒ₂Z_{M1})+C_{gb2}(1+gₘ₂rₒ₂+rₒ₂/Z_{M1})/(C_{gs2}C_{gd2}rₒ₂),

a₁−1/(C_{gd2}L_{g2}),

a₀=(1−gₘ₂rₒ₂+rₒ₂+rₒ₂/Z_{M1})/(C_{gs2}C_{gd2}rₒ₂L_{g2}),

b₂=1/(C_{gs2}rₒ₂)+1/(C_{gd2}rₒ₂)−gₘ₂/C_{gs2}+C_{gb2}/(C_{gs2}C_{gd2}rₒ₂),

b₀=1/(C_{gs2}C_{gd2}rₒ₂L_{g2}),

r₀₂ (704 of FIG. 7A) may represent the drain-source resistor of transistor M₂ (170 of FIG. 1B), and Z_{M1} (708 of FIG. 7A) may be the equivalent impedance looking into the drain of transistor M₁ (180 of FIG. 1B). L_{g2} (136 of FIG. 1B) and/or C_{gd2}_{_}ₑₓₜ (which may be included within C_{gd2}, element 412) may be chosen properly for enhanced reverse isolation in the desired frequency band of the proposed LNA. To simplify the assessment of the effect of L_{g2} (136) on the reverse isolation from Vₒᵤₜ_{_}_{LNA} (182) to V_{y}(184), Z_{M1}(708) may be replaced by the drain-source resistance (rₒ₁) of M₁ (180). Also illustrated in the model 700 of FIG. 7A with respect to M₂ (170 of FIG. 1B) are the gate-to-source capacitance (C_{gs2}, element 414), capacitance (C_{gb2}, element 406), gate-to-source voltage V_{gs2} (182), current source gₘ₂V_{gs2} (702), and ground (134).

FIG. 7B is a graph 750 indicating simulated reverse isolation from Vₒᵤₜ_{_}_{LNA} to V_{y} (752) with (756) and without (758) L_{g2}, plotted against frequency 754 (in Hertz) for the proposed LNA. The macromodel simulation result in FIG. 7B shows that the reverse isolation (V_{y}/Vₒᵤₜ_{_}_{LNA}, element 752) may have a notch (760) and may have a peak (762) as may be predicted by Equation (22). Note that the use of an ideal inductor for L_{g2} (138 of FIG. 1B) may result in a higher peak than an inductor with a lower quality factor.

The stability factor K of the proposed LNA may be defined (see for example, “A New Method to Stabilize High Frequency High Gain CMOS LNA,” and “A Noise Reduction and Linearity Improvement Technique for a Differential Cascode LNA”) as:

$$K = \frac{1 + {\vert Δ \vert}^{2} - {\vert S 11 \vert}^{2} - {\vert S 22 \vert}^{2}}{2 \cdot \vert S 21 \vert \cdot \vert S 12 \vert} , \qquad ( 23 )$$

where Δ may be defined as Δ=S11·S22−S12·S21. The unconditional stability requirement may be K>1 and/or |Δ|<1. S11 and/or S22 may be close to zero when the input and output of the proposed LNA are matched to the source and load impedances.

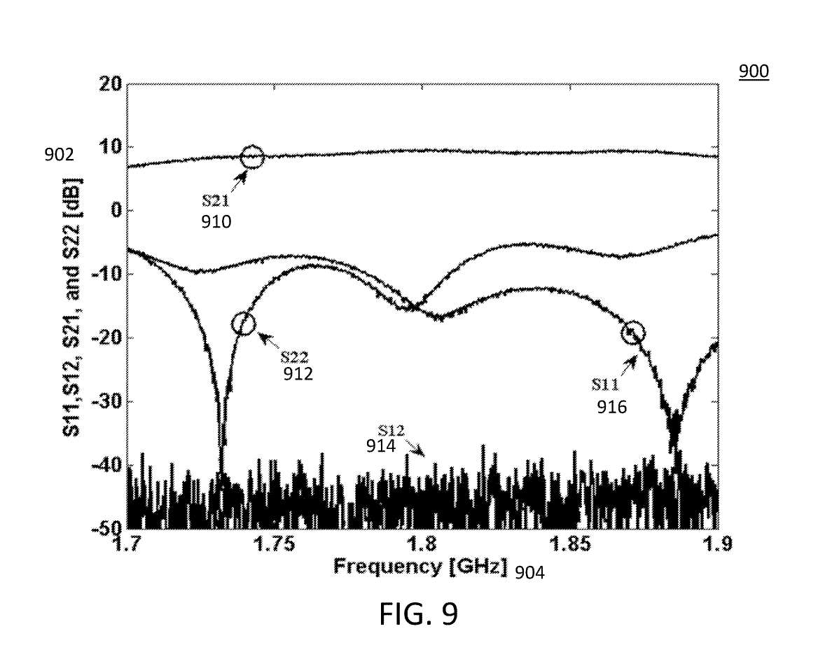

FIG. 9 is a graph 900 indicating measured scattering parameters of the proposed LNA with the buffer stage (−5.3 dB gain). Based on the measured S-parameters 902 (910, 912, 914, 916, collectively) of the proposed LNA and buffer stage combination, the value of |Δ| may be less than 1 and the value of K may be more than 1 in the frequency range from 0.1 GHz to 8.5 GHz. The |Δ| and K values may be 0.05 and 17.67 at 1.8 GHz, respectively.

From simulations of the proposed LNA without the buffer, the reverse isolation at 1.8 GHz with L_{g2}=3.5 nH (136 of FIG. 1B) and C_{gd2}_{_}ₑₓₜ=150 fF (138 of FIG. 1B) may be slightly better (−29.7 dB) than without L_{g2} (136 of FIG. 1B) and C_{gd2}_{_}ₑₓₜ (138 of FIG. 1B) which may result in a reverse isolation of −27.4 dB. As S12 decreases, the value of K may increase and the value of |Δ| may decrease, resulting in improved stability. However, the values of L_{g2} (136 of FIG. 1B) and C_{gd2}_{_}ₑₓₜ. (138 of FIG. 1B) may degrade reverse isolation and stability if they are not carefully selected. If L_{g2} (136 of FIG. 1B) and C_{gd2}_{_}ₑₓₜ (138 of FIG. 1B) are too large, then the peak of the transfer function in Equation (22) above may move from higher to lower frequency.

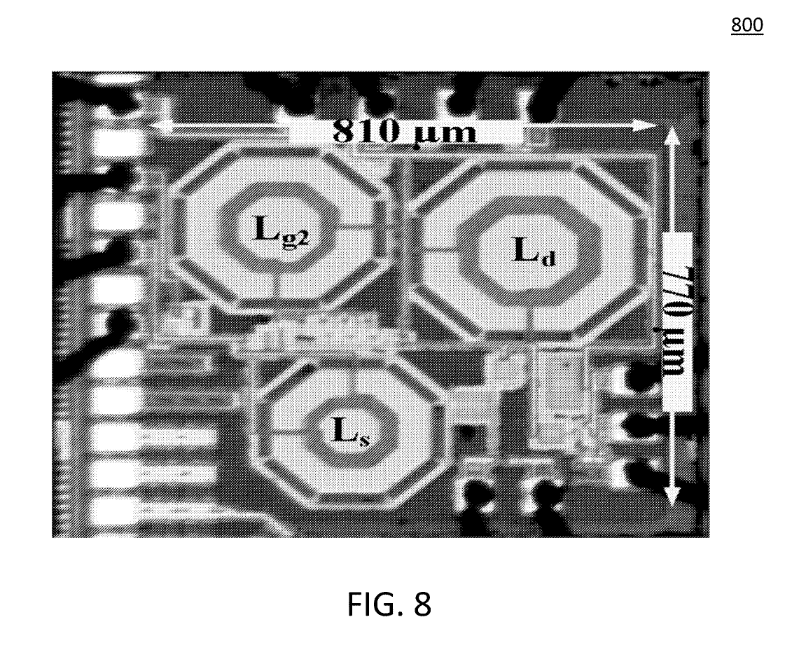

Measurement Results. FIG. 8 is an image 800 of a chip micrograph of the fabricated proposed LNA. As illustrated in FIG. 8, 1.8 GHz linearized subthreshold LNA may be designed and/or fabricated in 0.11 μm CMOS technology. FIG. 8 displays the chip micrograph 800 of the LNA with an area of 810 μm×770 μm.

Table I to follow lists the key design parameters of the proposed LNA. The proposed LNA may consume a 480 μA current (with exclusion of the buffer) from a 0.7 V power supply instead of the nominal 1.2 V supply voltage for a selected technology. In order to limit the linearity degradation due to the buffer (and/or output buffer) which may be designed to test the proposed LNA, a 1.2 V supply may be used for the buffer. Note that “the buffer,” “the output buffer,” and/or “buffer stage” may refer to M_{buffer} (154 of FIG. 1B) and/or its associated circuitry herein.

The value of L_{g2} (136 of FIG. 1B) in Table I may be selected to be 3.5 nH (with a quality factor of 6.5 at 1.8 GHz), and final post-layout simulations may be performed with foundry-supplied device models for on-chip components. The prototype chip may be bonded to a conventional QFN16 package that may be assembled on a printed circuit board for measurements.

TABLE I
LNA DESIGN PARAMETERS

| Component | Value | |
|---|---|---|
| V_{DD} | 0.7 | V |
| I_{D} | 480 | μA |
| g_{m, M1}/I_{D} | 22 | S/A |
| L_{g1} | 7.5 | nH |
| L_{g2} | 3.5 | nH |
| Lₛ | 2.4 | nH |
| C_{gs1 ext} | 130 | fF |
| C_{gd2 ext0} | 70 | fF |
| C_{gd2 ext1} | 20 | fF |
| C_{gd2 ext2} | 40 | fF |
| C_{gd2 ext3} | 80 | fF |
| L_{d} | 6.4 | nH |
| C_{d} | 88 | fF |
| R_{d} | 720 | Ω |

| | |
|---|---|
| W/L per finger (M_{1, 2}) | 6 μm/0.13 μm |
| Number of fingers (M_{1, 2}) | 64 |

Performance. Referring back to FIG. 2, the control switch settings (212, 214, and 216 of FIG. 2) for C_{gd2}_{_}ₑₓₜ (138 of FIG. 1B) of D₃D₂D₁=[100] (corresponding to elements 212, 214, and 216 of FIG. 2 being set high, low, and low, respectively) may result in preferable linearity of the discussed design after fabrication process variations. The optimal switch settings may vary for other designs. FIG. 9 shows 900 the measured scattering parameters 902 plotted against frequency 904 in GHz. The measured scattering parameters 902 may include S21 (910), S22 (912), S12 (914), and/or S11 (916) of the proposed LNA. As illustrated in FIG. 9, S11 (916) and/or S22 (912) may be below −10 dB at 1.8 GHz. The measured voltage gain of 9.5 dB at 1.8 GHz may be the combination of the proposed LNA with the buffer stage. As illustrated in FIG. 9, S12 (914) may be under −40 dB around the frequency of interest.

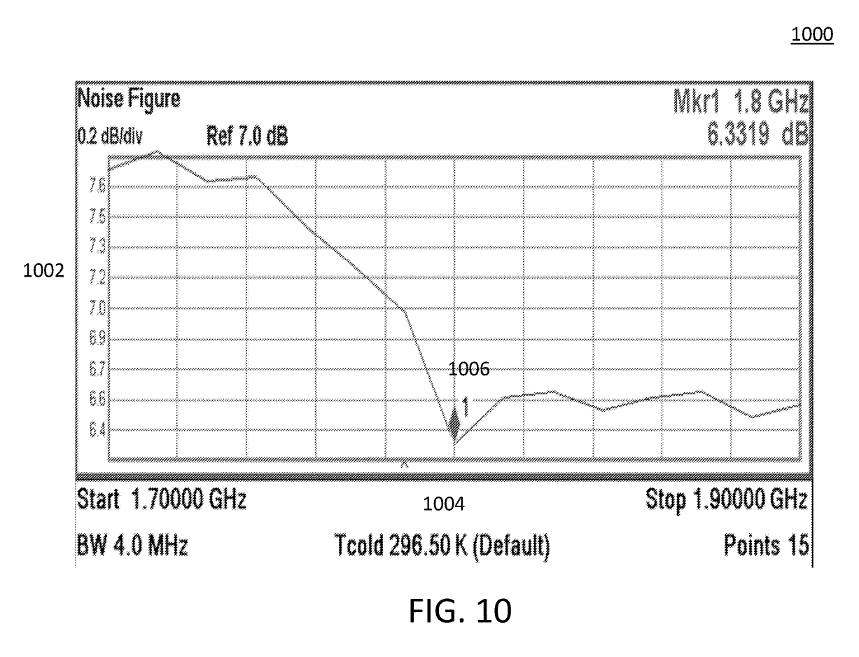

FIG. 10 is a graph 1000 (of noise 1002 versus frequency 1004), illustrating an example measured noise FIG. 1006 with the buffer stage (−5.3 dB gain) of the proposed LNA. FIG. 10 displays the plot of the measured noise figure (NF) 1006 that may be 6.3 dB at 1.8 GHz with the buffer. The voltage gain and noise FIG. 1006 of the LNA may be 14.8 dB and 3.7 dB after de-embedding the effects of the buffer stage loss, SMA cables and power combiner. As part of a de-embedding process, the simulated gain and noise FIG. 1006 of the proposed LNA and buffer combination may be compared to the measurement results. The overall noise figure difference between simulations and measurements may be within 0.8 dB, which may confirm that the measured LNA gain may be at least 14.8 dB because a significant reduction of the LNA gain may significantly degrade the overall noise figure of the combined proposed LNA and buffer stages. Note that the −5.3 dB gain of the buffer in FIG. 1B may be in the presence of parasitics due to the bonding, the integrated circuit package, and/or the PCB at the interface to the measurement equipment with 50Ω termination.

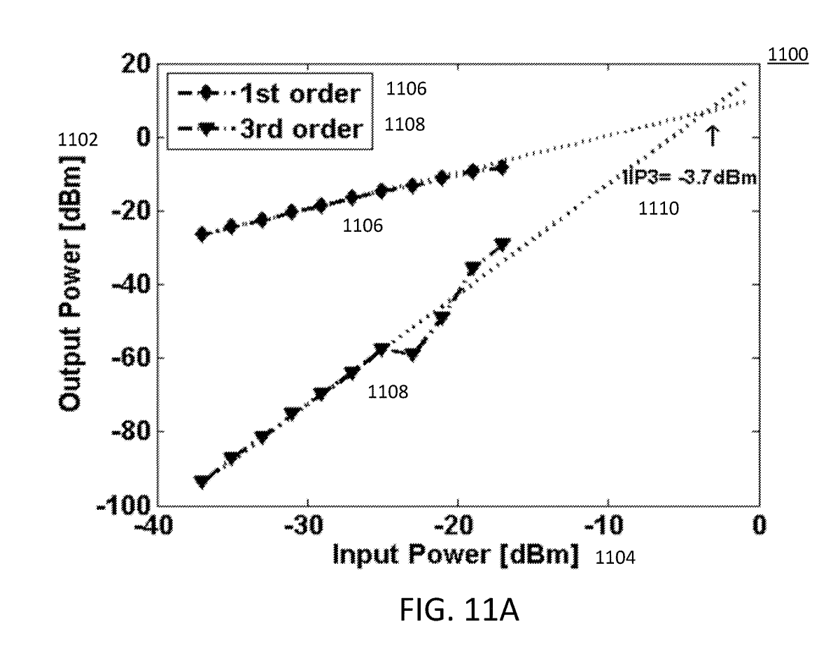

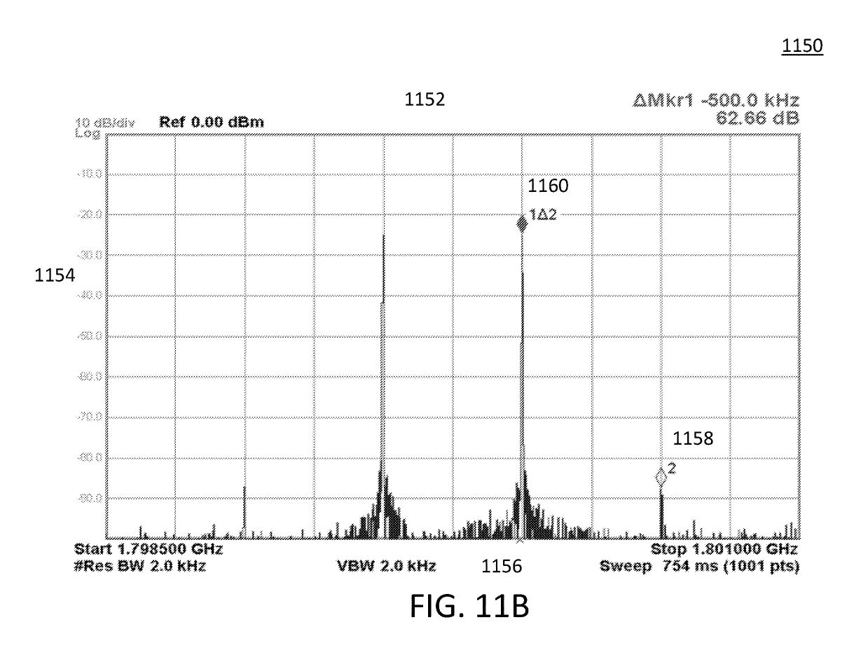

FIG. 11A is a graph 1100 of output power 1102 versus input power 1104, including 1st-order 1106 and 3rd-order 1108 components, and illustrating an example measured input IIP3 1110 of the proposed LNA with buffer stage (−5.3 dB gain).

FIG. 11B is a graph 1150 illustrating an example output spectrum 1152 (power 1154 versus frequency 1156) from a test with tones at 1.8 GHz (1158) and 1.7995 GHz (1160) and an input power of −35 dBm, according to the proposed LNA.

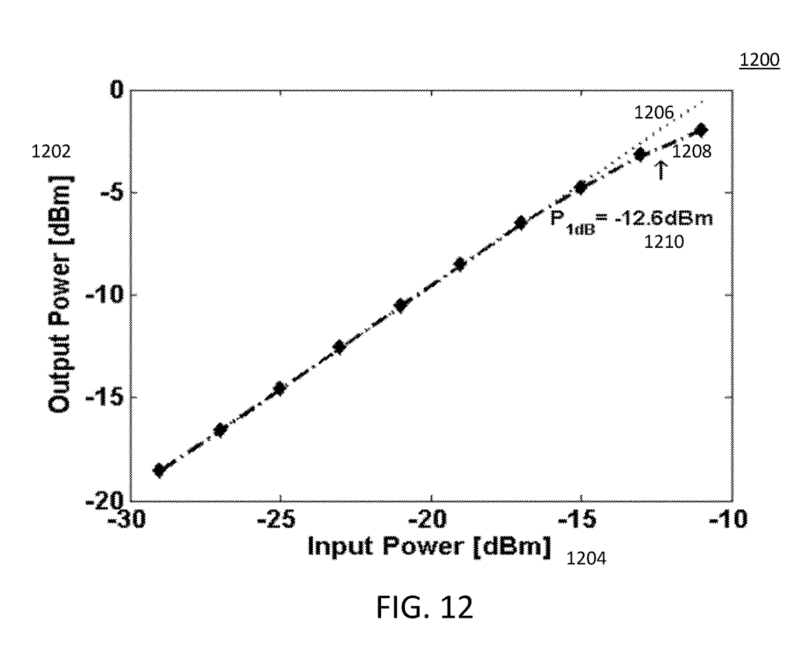

FIG. 12 is a graph 1200 illustrating an example measured input-referred 1-dB compression point of the proposed LNA with buffer stage (−5.3 dB gain) at 1.8 GHz. FIG. 12 illustrates a plot of output power measurements 1208 (output power 1202 versus input power 1204) from a power level sweep of a single 1.8 GHz tone to determine the 1-dB compression point (P_{1 dB}) of the LNA. Ideal power 1206 and measured power 1208 may be shown in FIG. 12. The corresponding IIP3 and P_{1 dB} (1210) of the proposed LNA may be −3.7 dBm and/or −12.6 dBm (1210) respectively.

Table II summarizes the performance of narrowband low-power RF LNAs with operating frequencies which may range from 1 GHz to 3 GHz in comparison to the proposed LNA.

TABLE II
COMPARISON OF MEASUREMENT RESULTS

| | proposed | | | | | | |
|---|---|---|---|---|---|---|---|
| | LNA* | [1] | [2] | [3] | [4] | [7]^{#} | [16] |
| F_{C} [GHz] | 1.8 | 2.4 | 3 | 2.4 | 1 | 2.1 | 1 |
| GAIN [DB] | 14.8 | 21.4 | 4.5 | 13.1 | 16.8 | 9.7 | 13.6 |
| NF [DB] | 3.7 | 5.2 | 6.3 | 5.3 | 3.9 | 4.36 | 4.6 |
| IIP3 [DBM] | −3.7 | −11 | −10.5 | −12.2 | −11.2 | −4 | 7.2 |
| P_{1DB} [DBM] | −12.6 | −15 | −19.5 | −19 | −21 | n/a | −0.2 |
| P_{DC} [MW] | 0.336 | 1.134 | 0.156 | 0.06 | 0.1 | 0.684 | 0.26 |
| TECH. [NM] | 110 | 180 | 130 | 130 | 180 | 90 | 180 |
| AREA [MM²] | 0.624^{$} | 0.717^{$} | 2^{‡} | 0.63^{$} | 0.809^{‡} | 0.91^{$} | 0.694^{$} |

*after de-embedding the effect of the buffer stage
^{#}fully differential structure
^{$}without pads
^{‡}with pads

In Table II above, [1] refers to reference “A Subthreshold Low-Noise Amplifier Optimized for Ultra-Low-Power Applications in the ISM Band;” [2] refers to reference “A 3 GHz Subthreshold CMOS Low Noise Amplifier;” [3] refers to reference “A 60 μW LNA for 2.4 GHz Wireless Sensors Network Applications;” [4] refers to reference “A Novel Ultra Low Power Low Noise Amplifier Using Differential Inductor Feedback;” [7] refers to reference “MOST Moderate-Weak-Inversion Region as the Optimum Design Zone for CMOS 2.4-GHz CS-LNAs;” and [16] refers to reference “A Fully Monolithic 260-μW, 4-GHz Subthreshold Low Noise Amplifier.”

IIP3 Tunability. Referring back to FIG. 2 of the proposed LNA, the minimum, maximum, and/or other capacitance values of C_{gd2}_{_}ₑₓₜ. (elements 202, 204, 206, and 208 of FIG. 2) may occur with D₃D₂D₁=[111] and/or D₃D₂D₁=[000] (where elements 212, 214, and 216 of FIG. 2 represent D₃, D₂, and D₃, respectively) where ‘1’ and ‘0’ may indicate that the switch is connected to V_{DD} or ground, respectively. Table III may list eight different capacitance combinations of the proposed LNA with the corresponding measurement results of gain and/or the third-order intermodulation distortion (IM3) when two tones at 1.8 GHz and 1.7995 GHz are applied with an input power of −35 dBm. Results of Table III may indicate that changing C_{gd2}_{_}ₑₓₜ from 70 fF to 210 fF may have a minor effect on the gain while permitting to digitally tune for optimum third-order linearity performance.

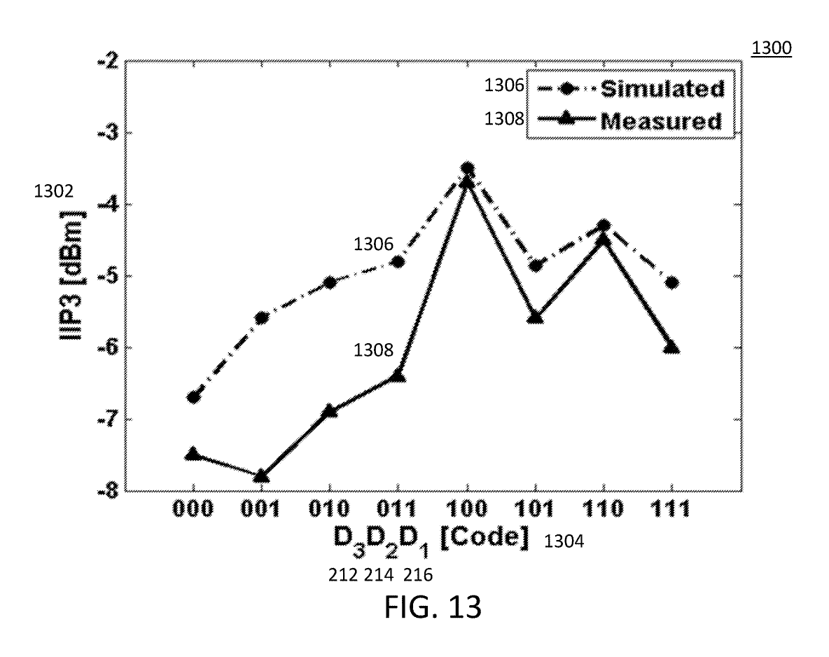

FIG. 13 is a graph illustrating an example IIP3 vs. C_{gd2}_{_}ₑₓₜ comparison (simulation vs. measurement results) 1300, according to the proposed LNA. FIG. 13 visualizes the IIP3 (1302) vs. tuning code (1304) from simulations (1306) and/or measurements (1308) with C_{gd2}_{_}ₑₓₜ capacitance values (where elements 212, 214, and 216 of FIG. 2 represent D₃, D₂, and D₃, respectively, shown in FIG. 13 and Table III). The measured results of FIG. 13 may demonstrate the feasibility of the proposed LNA to boost the IIP3 to achieve state-of-the-art overall LNA performance under consideration of the key parameters in Table II.

TABLE III
GAIN AND THIRD-ORDER INTERMODULATION
DISTORTION OF THE SUBTHRESHOLD LNA
FOR LINEARITY TUNING SETTINGS

| | Effective | | IM3 [dBc] |
|---|---|---|---|
| Code | C_{gd}_{_{—}}ₑₓₜ₂ | Gain* | with −35 dBm |
| [D₃D₂D₁] | Value [fF] | [dB] | input power |
| 000 | 70 | 14.1 | 55.0 |
| 001 | 90 | 13.7 | 54.4 |
| 010 | 110 | 14.2 | 56.2 |
| 011 | 130 | 14.3 | 57.3 |
| 100 | 150 | 14.8 | 62.7 |
| 101 | 170 | 13.8 | 58.8 |
| 110 | 190 | 14.2 | 61.0 |
| 111 | 210 | 14.0 | 58.1 |

*after de-embedding the effect of the buffer stage

The proposed LNA may include a 1.8 GHz subthreshold LNA with an IIP3 enhancement technique. The proposed LNA may be designed, analyzed, and fabricated in 0.11 μm CMOS technology. The proposed LNA may include extra passive components to accomplish full and/or partial cancellation of third-order nonlinearity products. The proposed LNA preferably does not require auxiliary amplification circuitry that may increase the power consumption. Therefore, the proposed LNA may be well-suited for low-power applications. Measurement results of the 0.336 mW LNA on the prototype chip may demonstrate an IIP3 of −3.7 dBm, a voltage gain of 14.8 dB, and/or a noise figure of 3.7 dB.

APPENDIX A, ANALYSIS OF THE INPUT STAGE. Referring back to FIG. 3 of the proposed LNA, the following equations may be written after applying Kirchhoff s current law to nodes 1, 2, and 3 (elements 350, 352, 354, respectively):

$$\begin{matrix}\frac{{V}_{x}}{{Z}_{11}} - ( j ω {C}_{gs 1} + j ω {C}_{gd 1} + j ω {C}_{gb 1} + \frac{1}{{Z}_{11}} ) {V}_{11} + j ω {C}_{gs 1} {V}_{12} + j ω {C}_{gd 1} {V}_{13} = 0 , & ( A .1 ) \\ j ω {C}_{gs 1} {V}_{11} - ( j ω {C}_{gs 1} + \frac{1}{{Z}_{12}} ) {V}_{12} + {i}_{d 1} = 0 , & ( A .2 ) \\ j ω {C}_{gd 1} {V}_{11} - ( j ω {C}_{gd 1} + \frac{1}{{Z}_{13}} ) {V}_{13} - {i}_{d 1} = 0 & ( A .3 )\end{matrix}$$

### Furthermore,

V_{gs1}=V₁₁−V₁₂ (A.4)

using (A.1) through (A.4) and the definitions of g_{M1}(ω) and Z₁₃(ω) above from Equations (4), (8), respectively, V_{gs1}(ω) may be derived as the following function of Vₓ (302) and i_{d1} (332):

$${V}_{gs 1} ( ω ) = \frac{1}{{g}_{M 1} ( ω )} [ \frac{( 1 + j ω {C}_{gd 1} {Z}_{13} ( ω ) ) {V}_{x}}{Z ( ω )} - {i}_{d 1} ] . \qquad ( A .5 )$$

The relation between Vₓ (302) and V₁₃ (326), where Vₓ (302) and V₁₃ (326) may be the input and output voltages of the input stage with transistor M₁ (element 180 of FIG. 1B) of the proposed LNA and may be expressed with a Volterra series as:

V₁₃(ω)=(C₁₁(ω)∘Vₓ+C₁₂(ω₁, ω₂)∘Vₓ+C₁₃(ω₁, ω₂, ω₃)∘Vₓ (A.6)

The relationship between the drain current (i_{d1}, element 332) and the gate voltage (V_{gs1}, element 318) of transistor M₁ (180) may be written in terms of its linear transconductance (g₁,m₁) and its nonlinear transconductance components (g_{2,M1}, g_{3,M1}, . . . ):

i_{d1}(V_{gs1})=g_{1,M1}V_{gs1}+g_{2,M1}V_{gs1}²+g_{3,M1}V_{gs1}³+ . . . . (A.7)

Furthermore, the relation between Vₓ (302) and V_{gs1} (318) in FIG. 3 may also be expressed with a Volterra series as:

V_{gs1}(ω)=A₁₁(ω)∘Vₓ+Aₗ₂ (ω₁, ω₂)∘Vₓ+A₁₂(ω₁, ω₂)∘Vₓ+A₁₃(ω₁, ω₂, ω₃)∘Vₓ . . . (A.8)

The linear transfer functions A₁₁(ω) and C₁₁(ω) above of the proposed LNA may be determined (see for example, “Linearization of CDMA Receiver Front-Ends,” “Modified Derivative Superposition Method for Linearizing FET Low-Noise Amplifier,” and “A Noise Reduction and Linearity Improvement Technique for a Differential Cascode LNA”) by applying a tone [Vₓ(ω)=e^{jωt}] in the analysis, which may result in:

$$\begin{matrix} {A}_{11} ( ω ) = \frac{1}{{g}_{1 , M 1} + {g}_{M 1} ( ω )} [ \frac{1 + j ω {C}_{gd 1} {Z}_{13} ( ω )}{Z ( ω )} ] , & ( A .9 ) \\ {C}_{11} ( ω ) = {Z}_{13} ( ω ) \frac{j ω {C}_{gd 1} d ( ω ) - [ d ( ω ) + e ( ω ) ] {g}_{1 , M 1} {A}_{11} ( ω )}{b ( ω ) + c ( ω ) + j ω {C}_{gs 1} Z ( ω )} ; \\ where \text{:} & ( A .10 ) \\ b ( ω ) = 1 + j ω {C}_{gd 1} {Z}_{13} ( ω ) , & ( A .11 ) \\ c ( ω ) = [ j ω {C}_{gs 1} + j ω {C}_{gd 1} + j ω {C}_{g b 1} - {ω}^{2} {C}_{gd 1} {C}_{g b 1} {Z}_{13} ( ω ) ] \cdot {Z}_{11} ( ω ) , & ( A .12 ) \\ d ( ω ) = 1 + j ω {C}_{gs 1} {Z}_{12} ( ω ) , & ( A .13 ) \\ e ( ω ) = [ j ω {C}_{gs 1} + j ω {C}_{gd 1} + j ω {C}_{g b 1} - {ω}^{2} {C}_{gs 1} {C}_{g b 1} {Z}_{12} ( ω ) ] \cdot {Z}_{11} ( ω ) . & ( A .14 )\end{matrix}$$

APPENDIX B, ANALYSIS OF THE CASCODE STAGE. Referring back to FIG. 4 of the proposed LNA, by applying Kirchhoff's current law to nodes 4 and 5 (elements, 450 and 452, respectively), the following equations may be obtained:

$$\begin{matrix}j ω {C}_{gs 2} ( {V}_{22} - {V}_{21} ) + \frac{{V}_{22}}{{Z}_{22}} + j ω {C}_{gd 2} ( {V}_{22} - {V}_{23} ) = 0 , & ( B .1 ) \\ j ω {C}_{gs 2} ( {V}_{23} - {V}_{22} ) + \frac{{V}_{23}}{{Z}_{23}} + {i}_{d 2} = 0. & ( B .2 )\end{matrix}$$

It may be noted that:

V_{gs2}=V₂₂−V₂₁ (B.3)

In equations (B.1) through (B.3), the g_{M2}(ω), Z₂₂(ω) and/or Z₂₃(ω) definitions may be determined from the above equations (14), (9), and (10). V_{gs2}(ω) may be found in terms of V₂₁ and i_{d2} as follows:

$$\begin{matrix} {V}_{gs 2} ( ω ) = \frac{1}{{g}_{M 2} ( ω )} [ \frac{f ( ω ) {V}_{21}}{j ω {C}_{gd 2} {Z}_{22} ( ω ) {Z}_{23} ( ω )} - {i}_{d 2} ] , where & ( B .4 ) \\ f ( ω ) = ( 1 + j ω {C}_{gd 2} {Z}_{23} ( ω ) ) \cdot [ 1 + j ω {C}_{gd 2} {Z}_{22} ( ω ) ] + {ω}^{2} {C}_{gd 12} {Z}_{22} ( ω ) {Z}_{23} ( ω ) & ( B .5 )\end{matrix}$$

The relationship between V₂₁ (410) and V₂₃ (430) in FIG. 4, where V₂₁ (410) and V₂₃ (430) may be the input and output voltages, respectively, of transistor M₂ (element 170 of FIG. 1B), may be written with Volterra series:

V₂₃(ω)=C₂₁(ω)∘V₂₁+C₂₂(ω₁, ω₂)∘V₂₁+C₂₃(ω₁, ω₃, ω₃)∘V₂₁ (B.6)

Referring back to FIG. 4, the relation between the drain current (i_{d2}, element 418) and the gate voltage (V_{gs2}, element 416) of transistor M₂ (170 of FIG. 1B) may be:

i_{d2}(V_{gs2})=g_{1,M2}V_{gs2}+g_{2,M2}V_{gs2}²+g_{3,M2}V_{gs2}²+ (B.7)

Furthermore, the relationship between V₂₁ (410) and V_{gs2} (416) of FIG. 4 may be expressed by applying Volterra series as:

V_{gs2}(ω)=A₂₁(ω)∘Vₓ+A₂₂(ω₁, ω₂)∘Vₓ+A₂₃(ω₁, ω₂, ω₃)∘Vₓ (B.8)

Correspondingly, the linear transfer functions A₂₁(ω) and C₂₁(ω) may be determined through single-tone analysis [using V₂₁(ω)=e^{jωt}], which may be:

$$\begin{matrix}{A}_{21} ( ω ) = \frac{1}{{g}_{1 , M 2} + {g}_{M 2} ( ω )} [ \frac{f ( ω )}{j ω {C}_{gd 2} {Z}_{22} ( ω ) {Z}_{23} ( ω )} ] , & ( B .9 ) \\ {C}_{21} ( ω ) = {Z}_{23} ( ω ) [ \begin{matrix}{g}_{1 , M 2} {A}_{21} ( ω ) \frac{1 + ( j ω {C}_{gs 2} + j ω {C}_{gd 2} )}{f ( ω )} - \\ \frac{{ω}^{2} {C}_{gs 2} {C}_{gd 2} {Z}_{22} ( ω )}{f ( ω )}\end{matrix} ] . & ( B .10 )\end{matrix}$$

The teachings of all patents, published applications and references cited herein are incorporated by reference in their entirety.

While this invention has been particularly shown and described with references to example embodiments thereof, it will be understood by those skilled in the art that various changes in form and details may be made therein without departing from the scope of the invention encompassed by the appended claims.

What is claimed is:

1. An amplifier comprising:
a field-effect transistor (FET) amplifier and a cascode FET, the cascode FET in series with the FET amplifier, each FET operating with a respective third-order nonlinearity coefficient and a respective linear gain, where each respective ratio of the respective third-order nonlinearity coefficient to the respective linear gain is positive;
an inductor added at a gate of the cascode FET, the inductor operatively coupled with other components in a circuit resulting in a first equivalent impedance looking into an input of the cascode FET from the FET amplifier, the first equivalent impedance substantially offsetting a distortion output of the FET amplifier based upon the added inductor; and
the inductor operatively coupled with the other components in the circuit resulting in a second equivalent impedance looking out of the gate of the cascode FET, the second equivalent impedance substantially offsetting a distortion output of the cascode FET based upon the added inductor.

2. The amplifier of claim 1, wherein the FET amplifier and the cascode FET operate in a programmable range of one or more operating frequencies between 0.3 GHz and 6 GHz.

3. The amplifier of claim 2, wherein the FET amplifier and the cascode FET each provide amplified output within a selected bandwidth associated with the one or more operating frequencies, the distortion output of the FET amplifier and the distortion output of the cascode FET being substantially offset within the selected bandwidth.

4. The amplifier of claim 1, wherein the FET amplifier and the cascode FET operates in at least one of a weak inversion region and a subthreshold region.

5. The amplifier of claim 1, wherein the other components include a capacitor connected between the gate of the cascode FET and a drain of the cascode FET, the capacitor adding to a parasitic gate-to-drain capacitance of the cascode FET, the capacitor further substantially offsetting the distortion output of the FET amplifier and the distortion output of the cascode FET.

6. The amplifier of claim 5, wherein the first equivalent impedance substantially offsets the distortion output of the FET amplifier based upon the added inductor and the capacitor.

7. The amplifier of claim 5, wherein the second equivalent impedance substantially offsets the distortion output of the cascode FET based upon the added inductor and the capacitor.

8. The amplifier of claim 5, wherein the capacitor is a programmable variable capacitor.

9. The amplifier of claim 1, wherein the distortion output of the FET amplifier is substantially offset by the first impedance, resulting in an improved value of an input third-order intermodulation intercept point (IIP3) of the FET amplifier, and the distortion output of the cascode FET is substantially offset of by the second impedance, resulting in an improved value of an input third-order intermodulation intercept point (IIP3) of the cascode FET.

10. The amplifier of claim 9, wherein the improved intermodulation intercept point (IIP3) value is improved by at least 3 dB.

11. An amplifier comprising:
a field-effect transistor (FET) amplifier and a cascode FET, the cascode FET in series with the FET amplifier, each FET operating with a respective third-order nonlinearity coefficient and a respective linear gain, where each respective ratio of the respective third-order nonlinearity coefficient to the respective linear gain is positive;
an inductor added at a gate of the cascode FET, the inductor operatively coupled with other components in a circuit resulting in a first equivalent impedance looking into an input of the cascode FET from the FET amplifier, the first equivalent impedance substantially offsetting a distortion output of the FET amplifier based upon the added inductor; and
a programmable capacitor connected between the gate of the cascode FET and a drain of the cascode FET, the programmable capacitor adding to a parasitic gate-to-drain capacitance of the cascode FET, the programmable capacitor further substantially offsetting the distortion output of the FET amplifier.

12. A method of amplifying comprising:
operating a field-effect transistor (FET) amplifier and a cascode FET, the cascode FET in series with the FET amplifier, and an inductor at a gate of the cascode FET, each FET operating with a respective third-order nonlinearity coefficient and a respective linear gain, where each respective ratio of the respective third-order nonlinearity coefficient to the respective linear gain is positive;
the inductor with other components in a circuit resulting in a first equivalent impedance looking into an input of the cascode FET from the FET amplifier, the first equivalent impedance substantially offsetting a distortion output of the FET amplifier based upon the added inductor; and
the inductor with the other components in the circuit further resulting in a second equivalent impedance looking out of the gate of the cascode FET, the second equivalent impedance substantially offsetting a distortion output of the cascode FET based upon the added inductor.

13. The method of claim 12, wherein the FET amplifier and the cascode FET operate in a programmable range of one or more operating frequencies between 0.3 GHz and 6 GHz.

14. The method of claim 13, wherein an output of the FET amplifier and an output of the cascode FET are each amplified within a selected bandwidth associated with the one or more operating frequencies, and the distortion output of the FET amplifier and the distortion output of the cascode FET are substantially offset within the selected bandwidth.

15. The method of claim 12, wherein the FET amplifier and the cascode FET operate in at least one of a weak inversion region and a subthreshold region.

16. The method of claim 12, wherein the other components include a capacitor connected between the gate of the cascode FET and a drain of the cascode FET, the capacitor adding to a parasitic gate-to-drain capacitance of the cascode FET, the capacitor further substantially offsetting the distortion output of the FET amplifier and the distortion output of the cascode FET.

17. The method of claim 16, wherein the first equivalent impedance substantially offsets the distortion output of the FET amplifier based upon the added inductor and the capacitor.

18. The method of claim 16, wherein the second equivalent impedance substantially offsets the distortion output of the cascode FET based upon the added inductor and the capacitor.

19. The method of claim 16, wherein the capacitor is a programmable variable capacitor.

20. The method of claim 12, wherein the distortion output of the FET amplifier is substantially offset by the first impedance, resulting in an improved value of an input third-order intermodulation intercept point (IIP3) of the FET amplifier, and the distortion output of the cascode FET is substantially offset of by the second impedance, resulting in an improved value of an input third-order intermodulation intercept point (IIP3) of the cascode FET.

21. The method of claim 20, wherein the improved intermodulation intercept point (IIP3) value is improved by at least 3 dB.

22. A method of amplifying comprising:
operating a field-effect transistor (FET) amplifier and a cascode FET, the cascode FET in series with the FET amplifier, and an inductor at a gate of the cascode FET, each FET operating with a respective third-order nonlinearity coefficient and a respective linear gain, where each respective ratio of the respective third-order nonlinearity coefficient to the respective linear gain is positive;
the inductor with other components in a circuit resulting in a first equivalent impedance looking into an input of the cascode FET from the FET amplifier, the first equivalent impedance substantially offsetting a distortion output of the FET amplifier based upon the added inductor; and
a programmable capacitor connected between the gate of the cascode FET and a drain of the cascode FET, the programmable capacitor adding to a parasitic gate-to-drain capacitance of the cascode FET, the programmable capacitor further substantially offsetting the distortion output of the FET amplifier.
